(19) United States
(12) Patent Application Publication
(10) Pub. No.: US 2012/0267612 A1
(43) Pub. Date: Oct. 25, 2012

(54) CROSS-LINKABLE COPPER PHTHALOCYANINE COMPLEXES

(75) Inventors: Chuanjun Xia, Lawrenceville, NJ (US); Raymond Kwong, Westhampton, NJ (US); Ken-Tsung Wong, Tapei County (TW); Hsiao-Fan Chen, Taipei (TW); Ming-Chen Kuo, Taichung County (TW); Kwang-Ohk Cheon, Holland, PA (US)

(73) Assignee: UNIVERSAL DISPLAY CORPORATION, Ewing, NJ (US)

(21) Appl. No.: 13/142,086

(22) PCT Filed: Jan. 14, 2009
(86) PCT No.: PCT/US09/30914

§ 371 Date: Jul. 28, 2011

(51) Int. Cl. C07F 1/08; H01L 51/44; H01L 51/48

(52) U.S. Cl. 257/40; 438/99; 540/140; 540/135; 257/E51.026; 257/E51.025

(57) ABSTRACT

Cross-linkable copper complexes comprising a copper phthalocyanine core and one or more cross-linkable functionalities linked to the phthalocyanine core. The copper complex may have a spacer group with the one or more cross-linkable functionalities on the spacer group. The spacer group contains a chain or one or more aryl groups. These cross-linkable copper complexes may be used in making organic electronic devices, such as OLEDs, by solution processing techniques.

### JOINT RESEARCH AGREEMENT

The claimed inventions were made by, on behalf of, and/or in connection with a joint research agreement between the Universal Display Corporation and National Taiwan University. The agreement was in effect on and before the date the claimed inventions were made, and the claimed inventions were made as a result of activities undertaken within the scope of the agreement.

### TECHNICAL FIELD

The present invention relates to materials for making organic electronic devices, such as organic light emitting devices.

### BACKGROUND

Many of the types of organic materials (e.g., small molecular materials) used in making organic light emitting devices (OLEDs) are conventionally deposited by vacuum deposition. For example, in some OLEDs, the hole injection layer is formed by the vacuum deposition of copper phthalocyanine (CuPc). More recently, inkjet printing has been used to directly deposit organic thin films in the fabrication of OLEDs. However, many small molecule materials used in the fabrication of OLEDs are not soluble in organic solvents and therefore, cannot be deposited by inkjet printing. Thus, there is a need for materials that can be used for fabricating OLEDs by solution processing in organic solvents.

### SUMMARY

Disclosed herein are cross-linkable copper complexes having a copper phthalocyanine (CuPc) core. These cross-linkable copper complexes may be used for making organic electronic devices, such as OLEDs, by solution processing techniques.

In one aspect, the present invention provides a cross-linkable copper complex having the following structure:

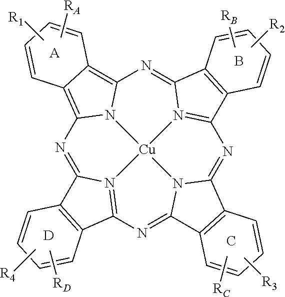

wherein R₁, R₂, R₃, and R₄ are each independently one or more optional substitutions with the proviso that at least one of R₁, R₂, R₃, and R₄ is a substitution comprising a spacer group and one or more cross-linkable functionalities on the spacer group, wherein the spacer group comprises a chain of one or more aryl groups; and

wherein R_{A}, R_{B}, R_{C}, and R_{D} are each independently one or more optional substitutions on any position of their respective rings A, B, C, and D, and each substitution being independently selected from the group consisting of: lower aliphatic, lower aryl, lower heteroaryl, and halogen.

In another aspect, the present invention provides a method of forming an organic layer, comprising: providing a solution containing a cross-linkable copper complex that comprises a phthalocyanine core and one or more cross-linkable functionalities linked to the phthalocyanine core; depositing the solution on a surface; and cross-linking the cross-linkable copper complex to form an organic layer on the surface.

In another aspect, the present invention provides an organic electronic device comprising: a first electrode; a second electrode disposed over the first electrode; and an organic layer disposed between the first electrode and the second electrode, wherein the organic layer comprises a cross-linked material having a plurality of cross-linked copper phthalocyanine molecular subunits.

### BRIEF DESCRIPTION OF THE DRAWINGS

FIG. 1 shows the structure of an OLED according to an embodiment of the invention.

FIG. 2 shows the absorption spectrum of a copper complex according to an embodiment of the invention (Compound 2).

FIG. 3 shows time-of-flight mass spectrometry results of a copper complex according to an embodiment of the invention (Compound 2).

FIG. 4 shows a plot of current density vs. applied voltage for various OLEDs, including those according to an embodiment of the invention.

### DETAILED DESCRIPTION

The meaning of the following terms, as intended to be used herein, are as follows:

The term “aliphatic” means a saturated or unsaturated hydrocarbyl in a linear, branched, or non-aromatic ring. The carbons can be joined by single bonds (alkyls), double bonds (alkenyls), or triple bonds (alkynyls). Besides hydrogen, other elements such as oxygen, nitrogen, sulfur, or halogens can be bound to the carbons as substitutions. The term “aliphatic” also encompasses hydrocarbyls containing heteroatoms, such as oxygen, nitrogen, or sulfur in place of carbon atoms. As such, as used herein, the term “aliphatic” includes esters, ethers, thioesters, thioethers, amines, and amides.

The term “alkyl” means alkyl moieties and encompasses both straight and branched alkyl chains. Additionally, the alkyl moieties themselves may be substituted with one or more substituents. The term “heteroalkyl” means alkyl moieties that include heteroatoms.

The term “lower,” when referring to an aliphatic or any of the above-mentioned types of aliphatics, means that the aliphatic group contains 1-15 carbon atoms. For example, lower alkyl groups include methyl, ethyl, propyl, isopropyl, butyl, isobutyl, tert-butyl, and the like.

The term “aryl” means a hydrocarbyl containing at least one aromatic ring, including single-ring groups and polycyclic ring systems. The term “heteroaryl” means a hydrocarbyl containing at least one heteroaromatic ring (i.e., containing heteroatoms), including single-ring groups and polycyclic ring systems. The polycyclic rings may have two or more rings in which two carbon atoms are common by two adjoining rings (i.e., the rings are “fused”), wherein at least one of the rings is aromatic or heteroaromatic. The term “lower aryl” or “lower heteroaryl” means an aryl or heteroaryl, respectively, containing from 3-15 carbon atoms.

Examples of aryl groups include benzene, naphthalene, anthracene, phenanthrene, perylene, pyrene, triphenylene, and those derived therefrom. Examples of heteroaryl groups include furan, benzofuran, thiophen, benzothiophen, pyrrole, imidazole, oxazole, tetrazole, indole, carbazole, pyridine, pyrazine, pyrimidine, quinoline, and those derived therefrom.

In one aspect, the present invention provides a cross-linkable copper complex comprising a copper phthalocyanine core and one or more cross-linkable functionalities linked to the phthalocyanine core. In certain embodiments, the cross-linkable copper complex has the following structure:

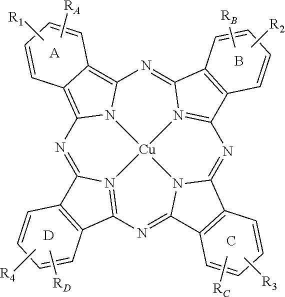

Each of R_{A}, R_{B}, R_{C}, and R_{D} are independently one or more optional substitutions on any position of their respective rings A, B, C, and D, with each such substitution independently being a lower aliphatic, a lower aryl, a lower heteroaryl, or a halogen. For example, R_{A}, R_{B}, R_{C}, and/or R_{D} may be a methyl group substitution on its respective, ring.

Each of R₁, R₂, R₃, and R₄ independently represents one or more optional substitutions, with the proviso that at least one of R₁, R₂, R₃, and R₄ is a substitution comprising a spacer group and one or more cross-linkable functionalities on the spacer group (e.g., at a terminal end of the spacer group). Where two or more of R₁, R₂, R₃, and R₄ are such substitutions, each substitution may be selected independently such that two or more of the substitutions are different from each other (e.g., the spacer groups and/or the cross-linkable functional groups may be different from each other). The spacer group is attached to their respective rings A, B, C, or D by a bond linkage or by ring fusion.

At least one of the spacer group(s) contains a chain of one or more aryl groups. The number and/or arrangement of the aryl group(s) in the chain can be selected to facilitate the ability of the cross-linking functional groups to engage in cross-linking reactions and/or to increase its solubility in organic solvents. For example, increasing the length of the chain can facilitate cross-linking by reducing steric interference to the cross-linking functional groups. Also, increasing the length of the chain may be useful in increasing the solubility (in an organic solvent) of the copper complex. As such, in some cases, the spacer group may separate the cross-linking functional group from its respective ring on the phthalocyanine core (i.e., rings A, B, C, or D) by a distance of at least 4 bond lengths; and in some cases, this distance may be at least 7 bond lengths. In such cases, the spacer group may separate the cross-linking functional group from its respective ring on the phthalocyanine core by a distance of up to 30 bond lengths. Also, the chain of aryl group(s) may be designed to have increased flexibility or to impart increased range of motion or degrees of freedom to the cross-linking functional groups.

In certain embodiments, the chain of aryl group(s) is directly linked to its respective ring on the phthalocyanine core. In certain embodiments, the aryl group(s) in the chain are monocyclic aryl groups (e.g., phenyl groups or substituted phenyl groups). In some cases, at least one of the spacer group(s) may contain from 1-6 monocyclic aryl groups. In some cases, where there are two or more monocyclic aryl groups in the chain, the aryl groups may be linked via meta linkages. Having meta-linked aryl groups in the chain may be useful in increasing the solubility (in an organic solvent) of the copper complex. In some cases, the molecular weight of the cross-linkable copper complex is 3,000 or less.

In addition to containing the chain of aryl group(s), the spacer group may contain one or more bonds and/or aliphatic linkage units, such as alkyl, alkenyl, ether, ester, amine, imine, amide, imide, thioether, or phosphine units. In some instances, the spacer group(s) contains a nitrogen. For example, the spacer group(s) may contain an amine group, such as a triphenylamine structure. Without intending to be bound by theory, it is believed that amino groups can modulate the HOMO and LUMO levels to enhance the electrochemical properties of the cross-linkable copper complex. As such, when the copper complex is used in an organic electronic device, a copper complex having a spacer group containing an amino group can be used to tune or enhance the performance of the organic electronic device.

Examples of spacer groups that can be used in the present invention include the following:

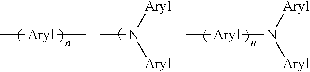

wherein n=1-6. Each of the aryl groups shown above may be selected independently (i.e., they may be same or different). One or more cross-linkable functional groups may be located anywhere on these spacer groups, such as the terminal aryl group(s).

Various types of cross-linking functionalities are known in the art, including those derived from amines, imides, amides, alcohols, esters, epoxides, siloxanes, moieties containing unsaturated carbon-carbon bonds, and strained ring compounds. For example, the cross-linking functionalities may be a vinyl, acrylate, epoxide, oxetane, trifluoroethylene, fused cyclobutene, siloxane, maleimide, cyanate ester, ethynyl, nadimide, phenylethynyl, biphenylene, phthalonitrile, or boronic acid. The number of cross-linking functional groups for each of rings A, B, C, and D will vary. In some cases, there are 0-5 cross-linking functional groups associated with each of rings A, B, C, and D.

Examples of cross-linkable copper complexes of the present invention include the following:

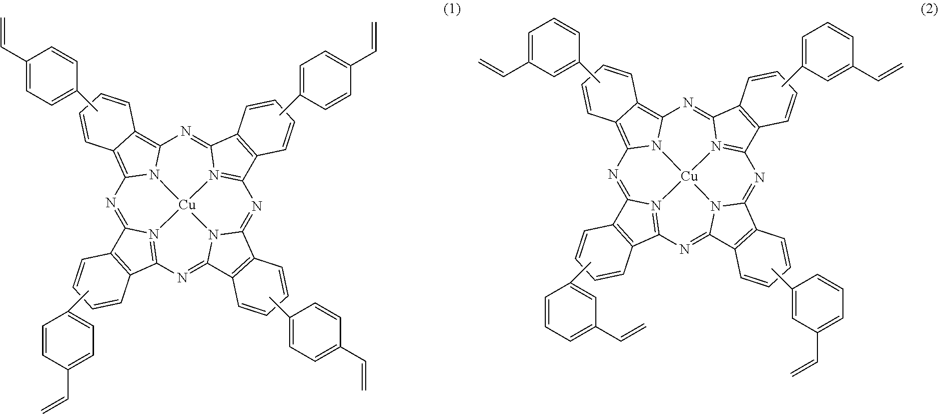

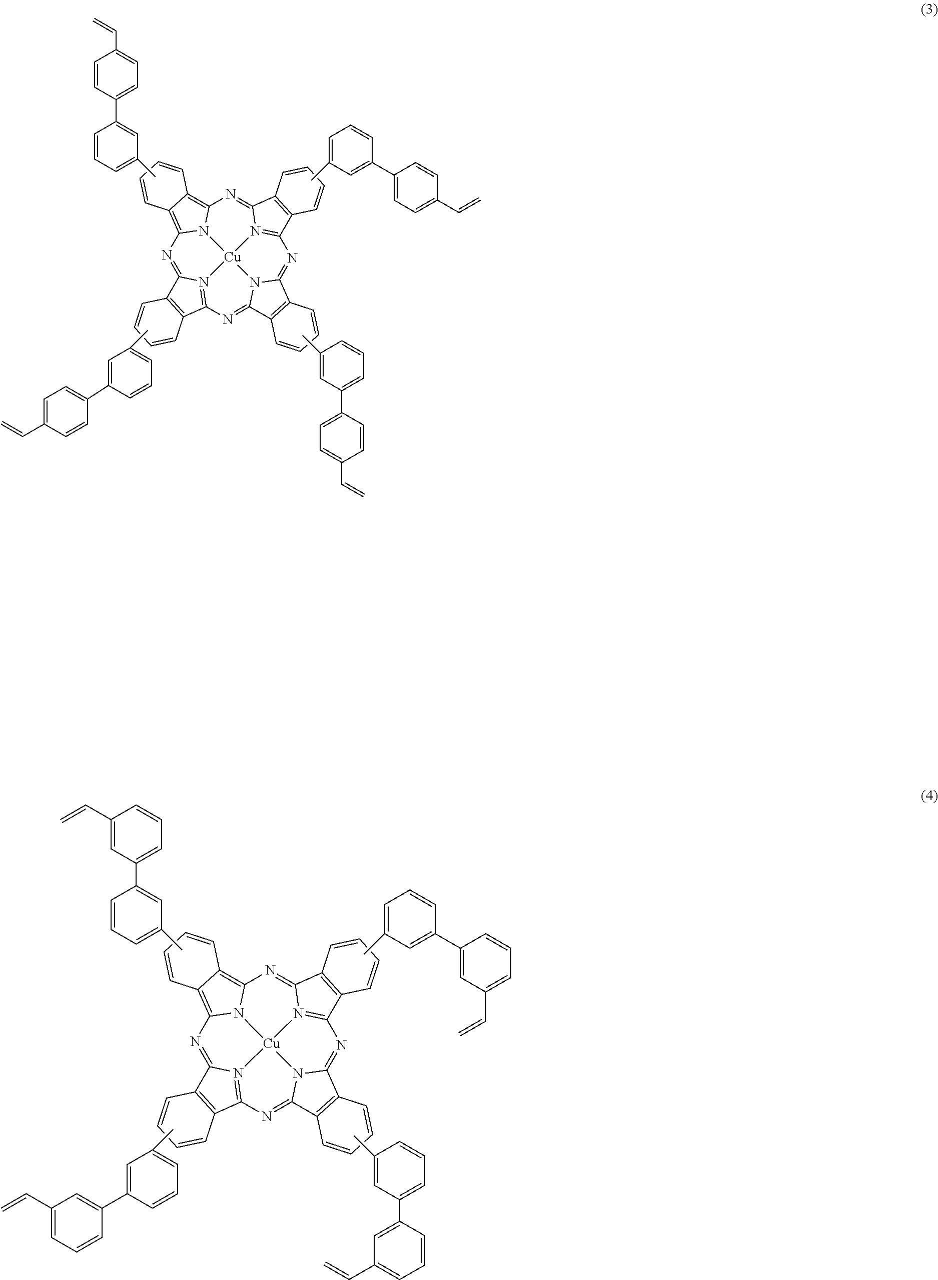

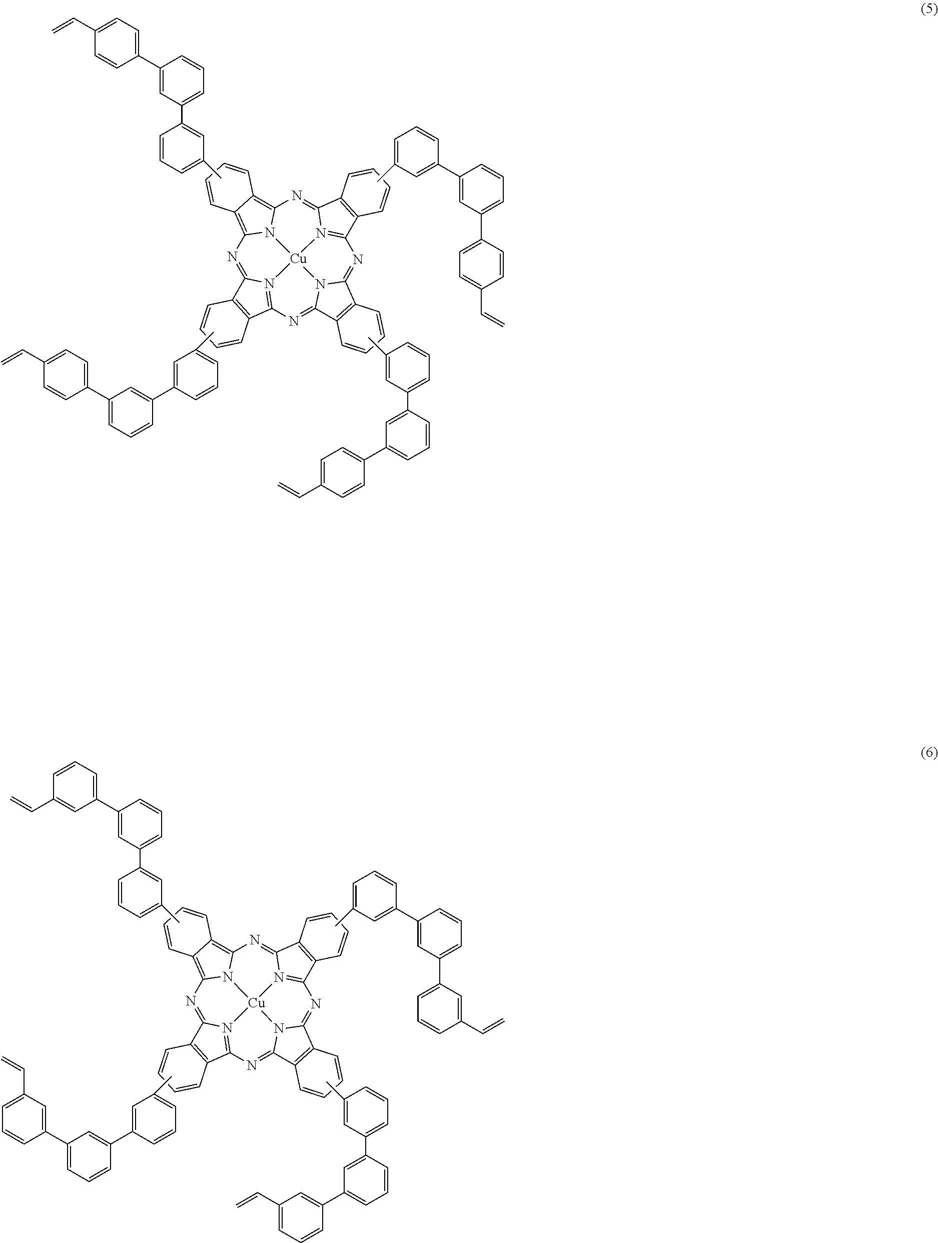

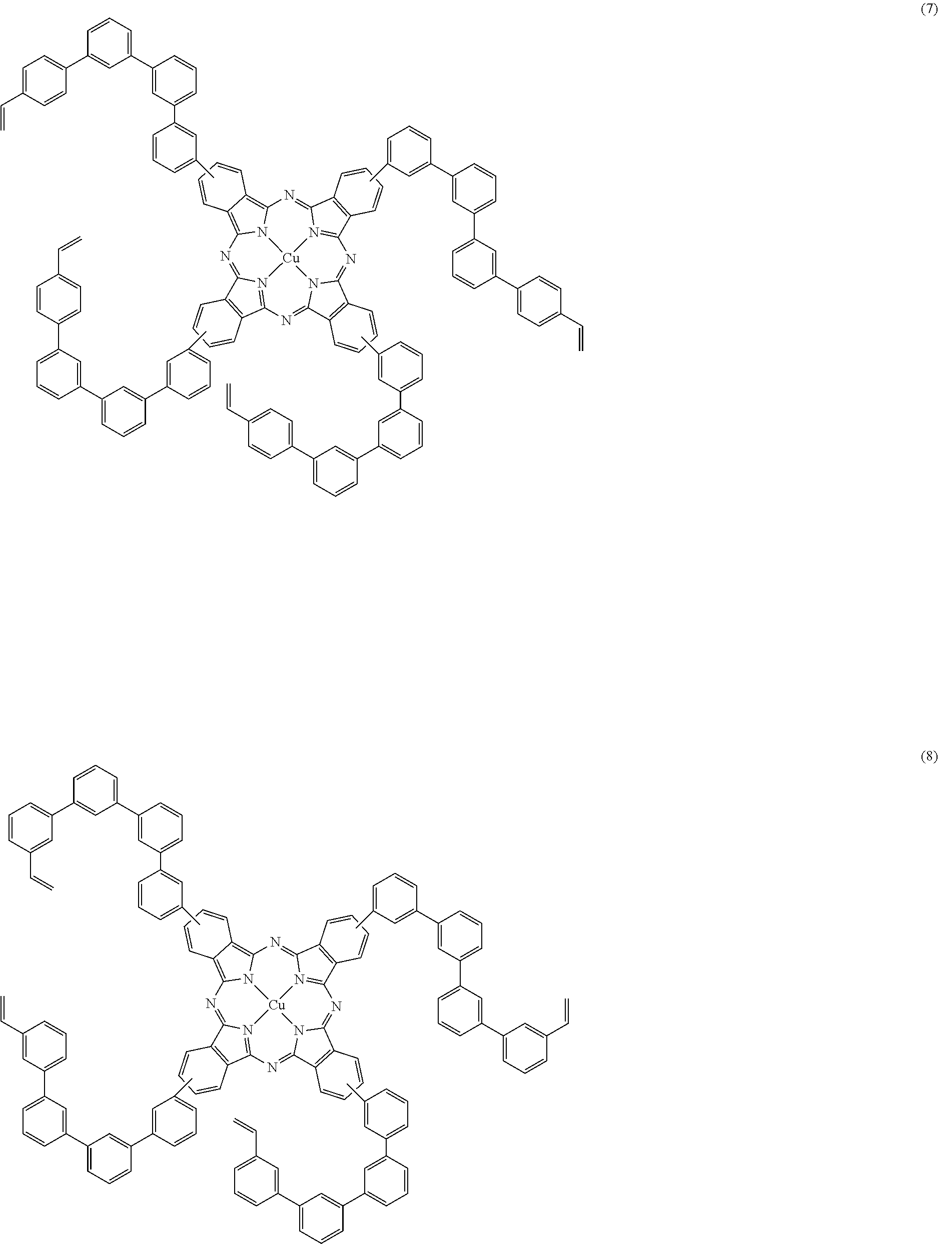

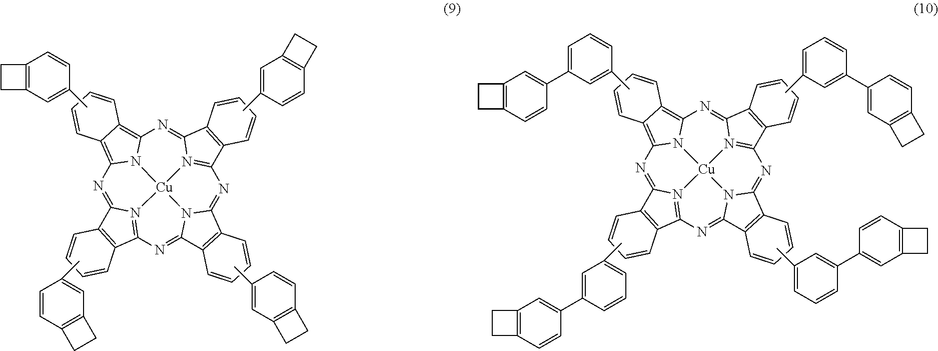

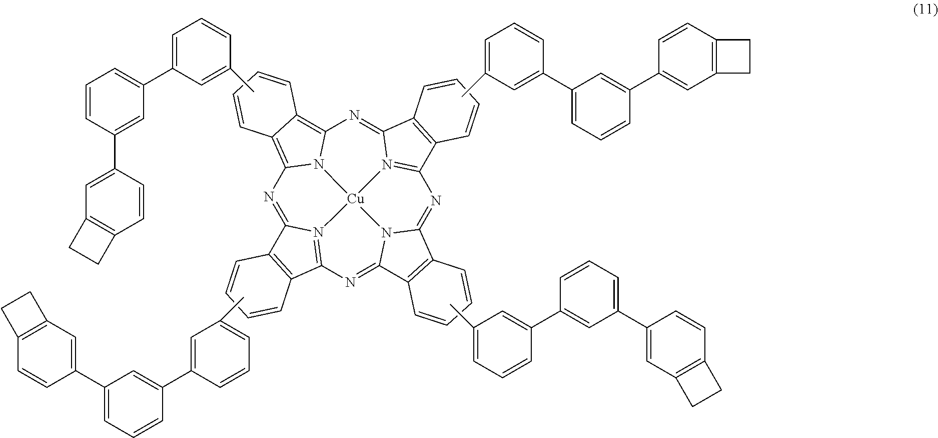

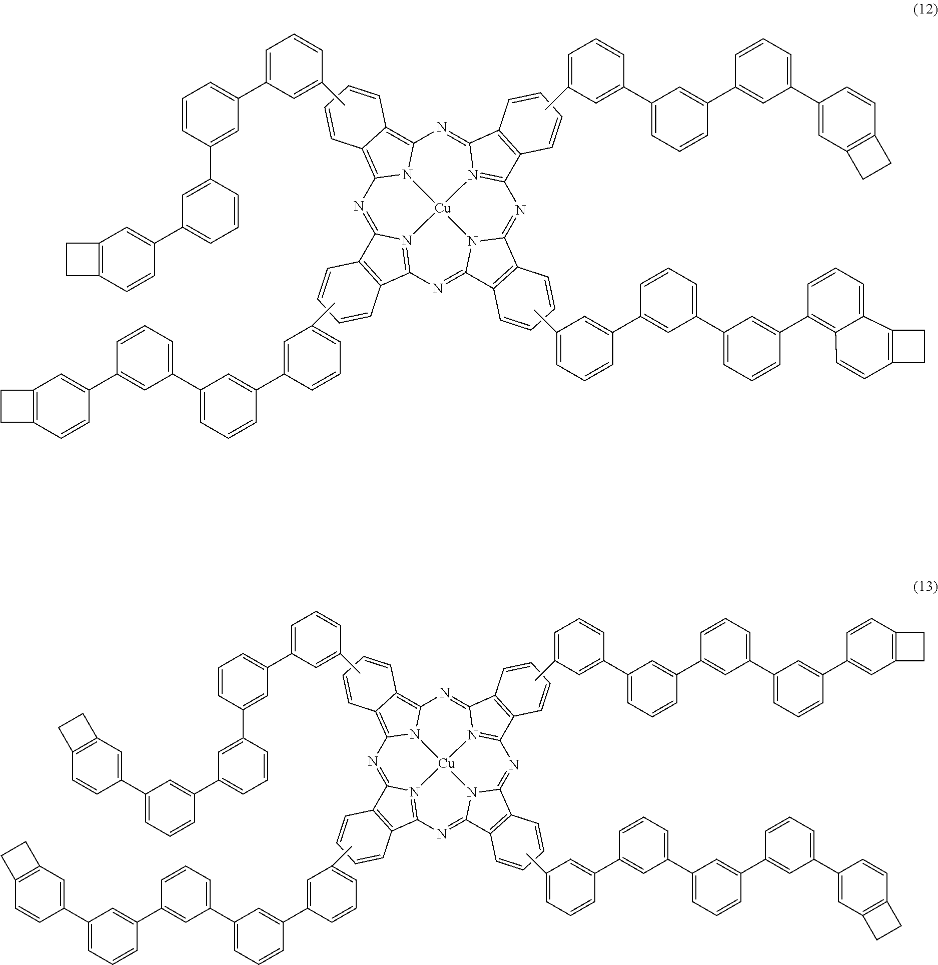

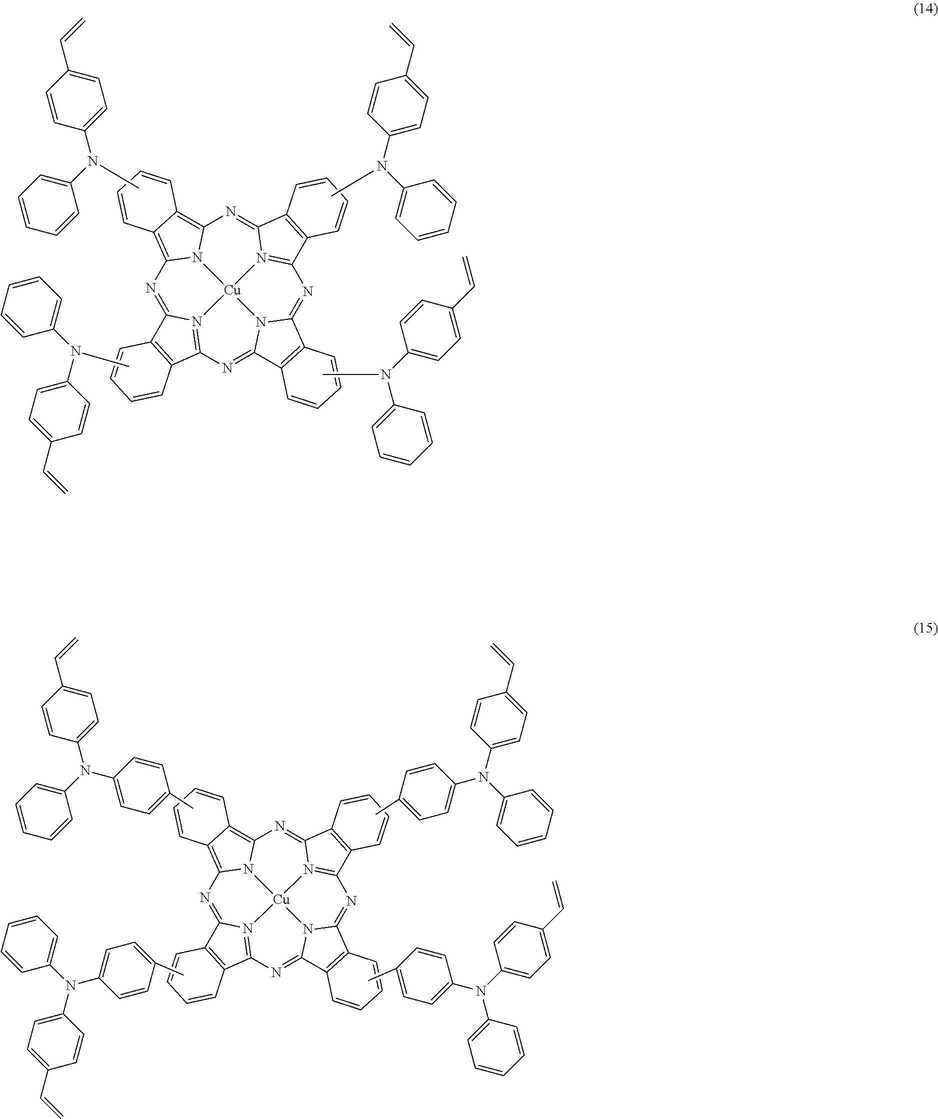

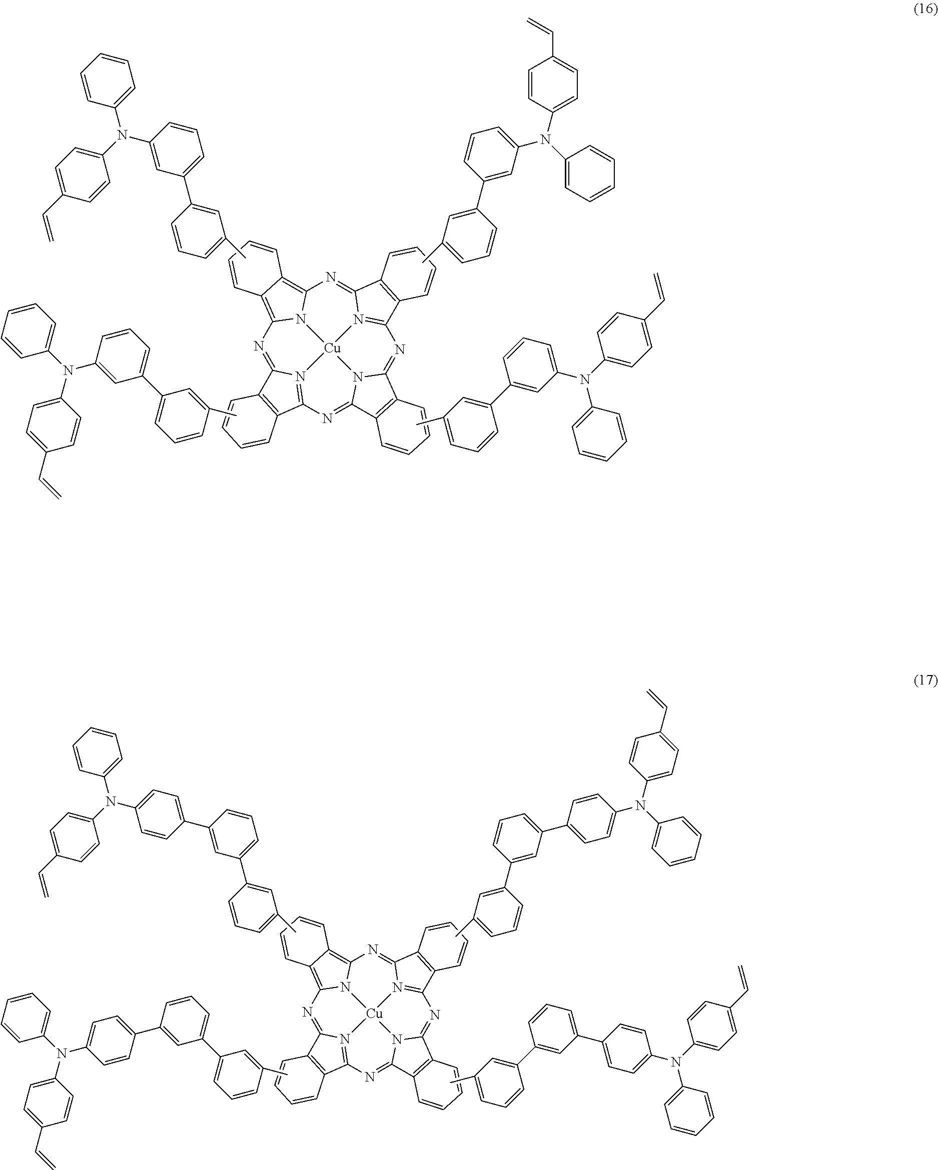

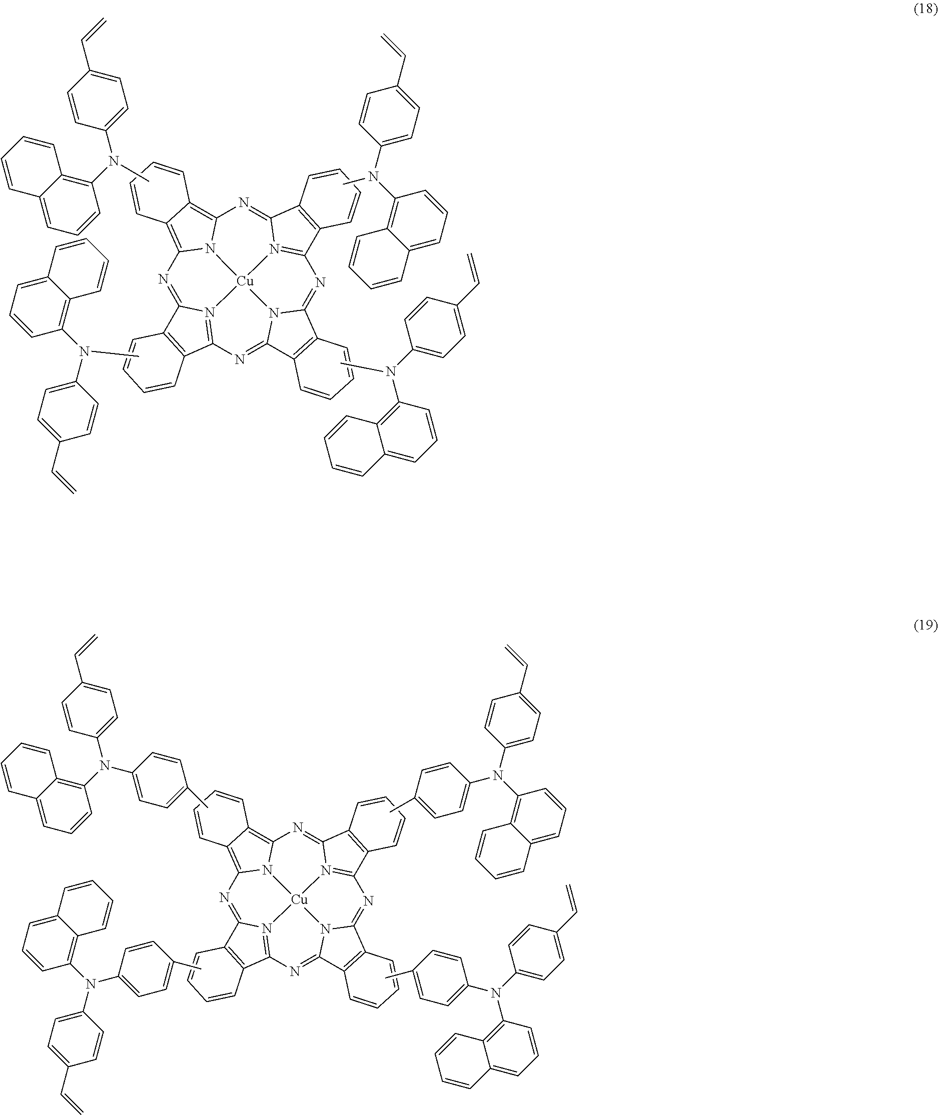

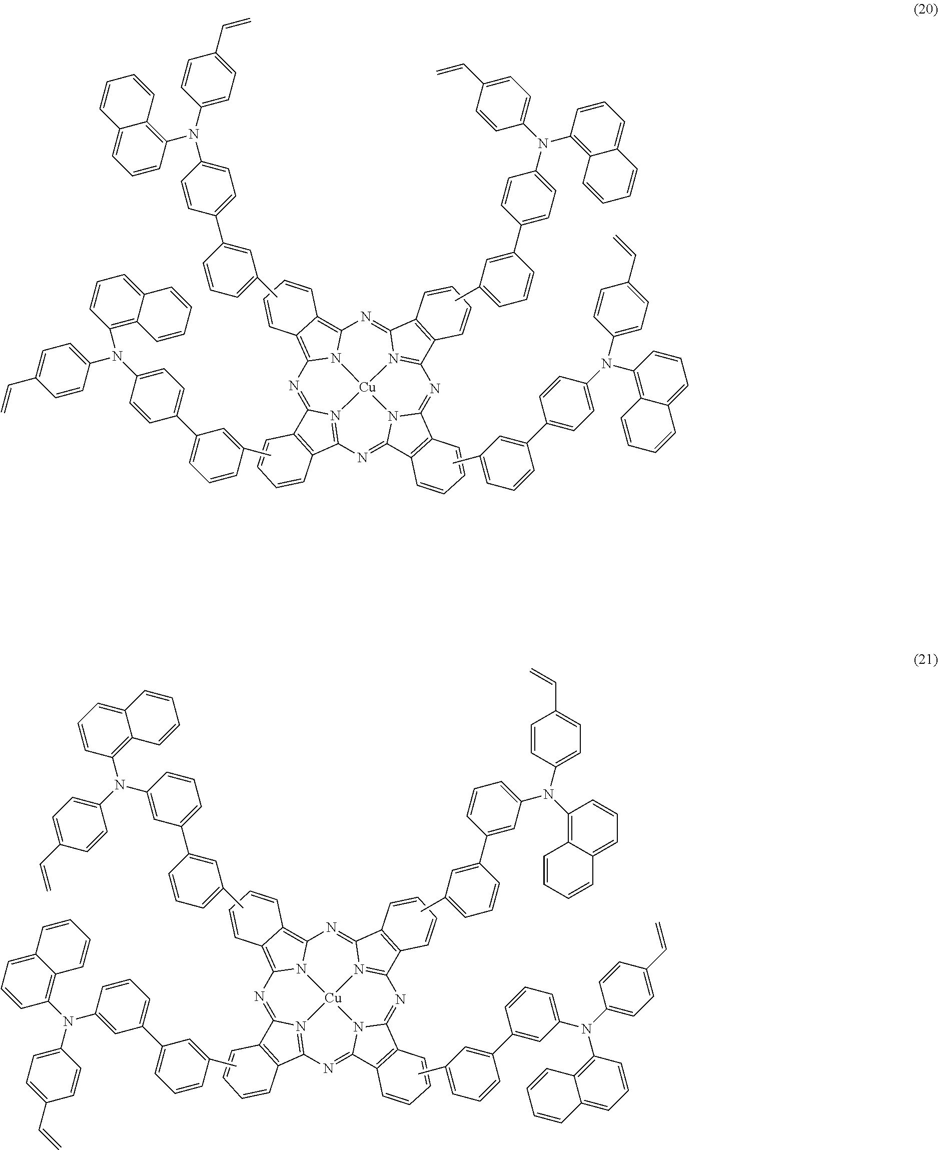

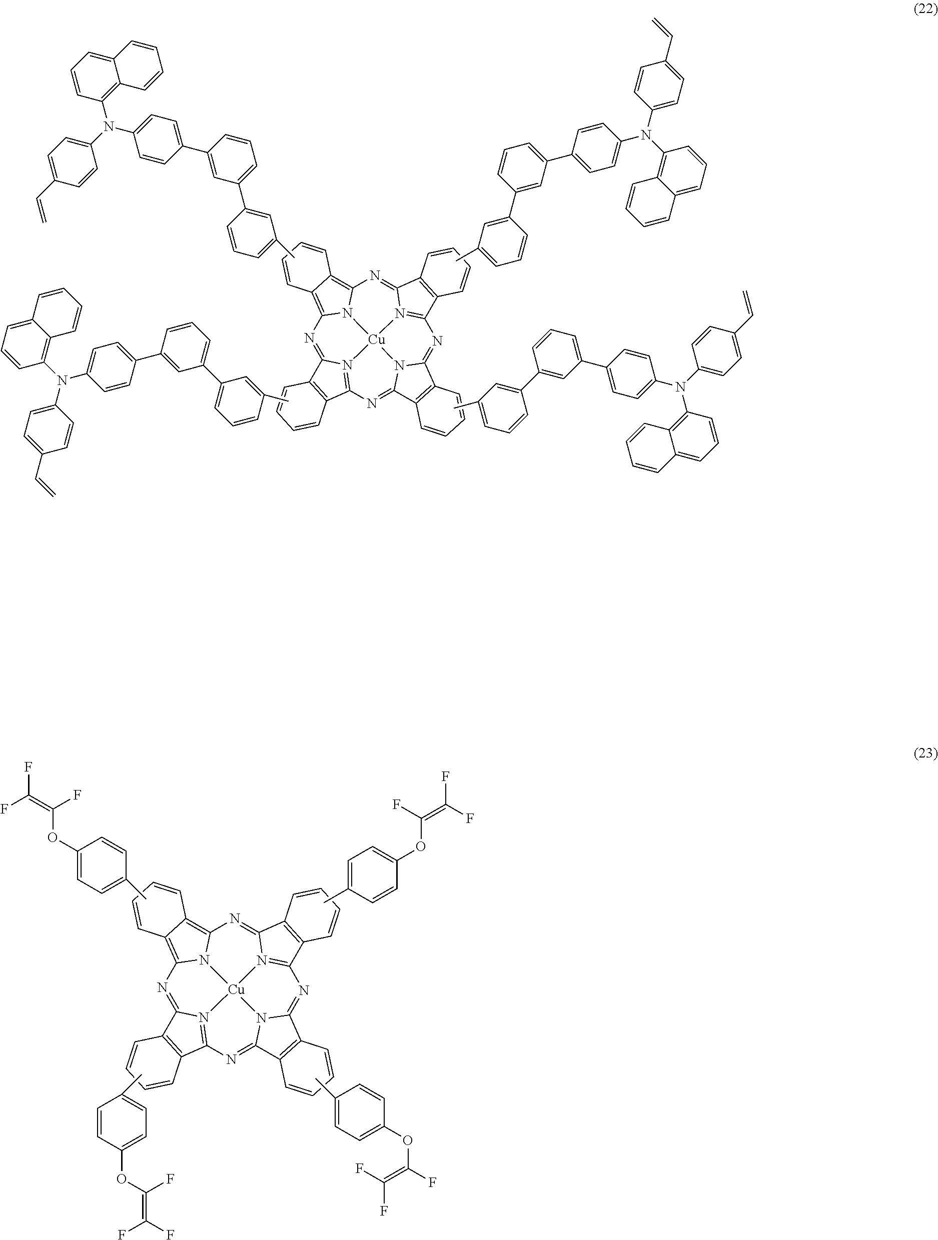

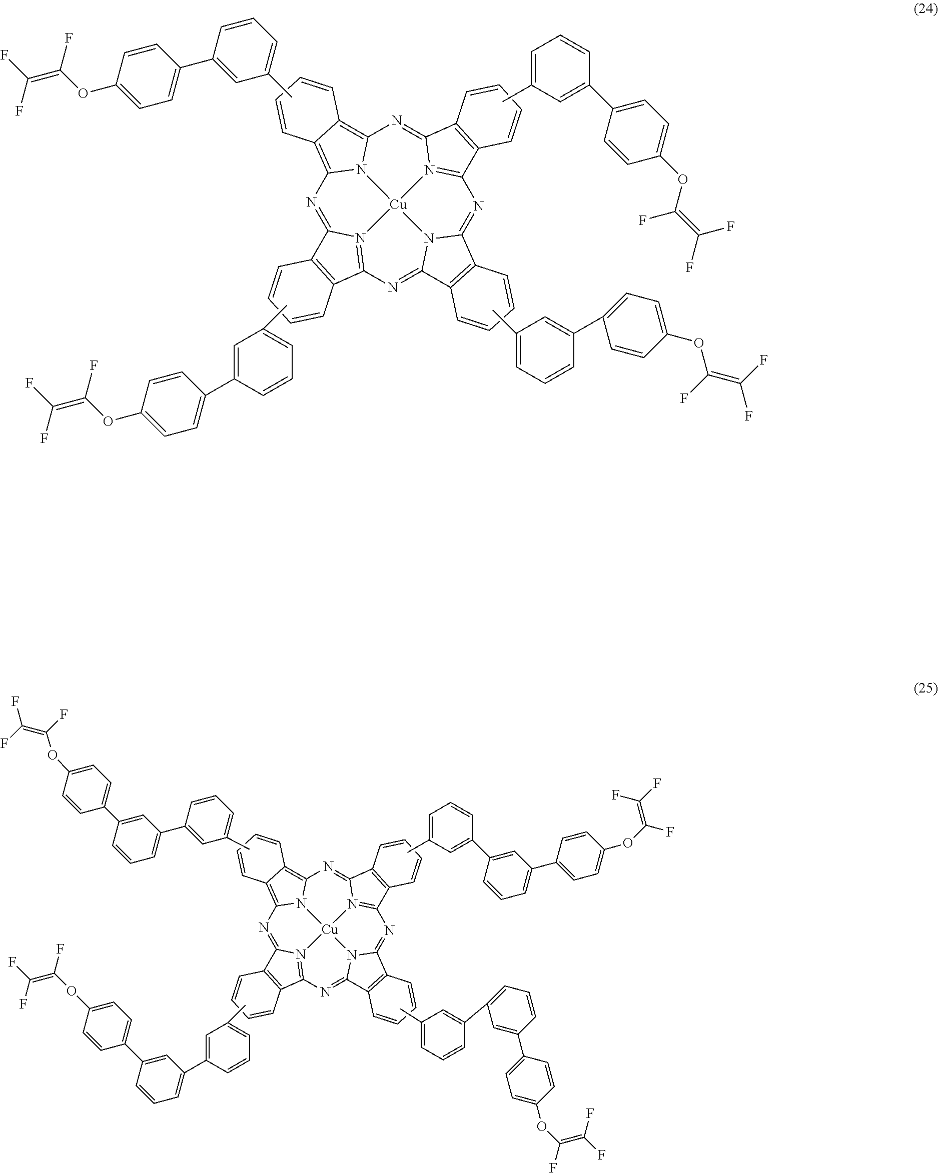

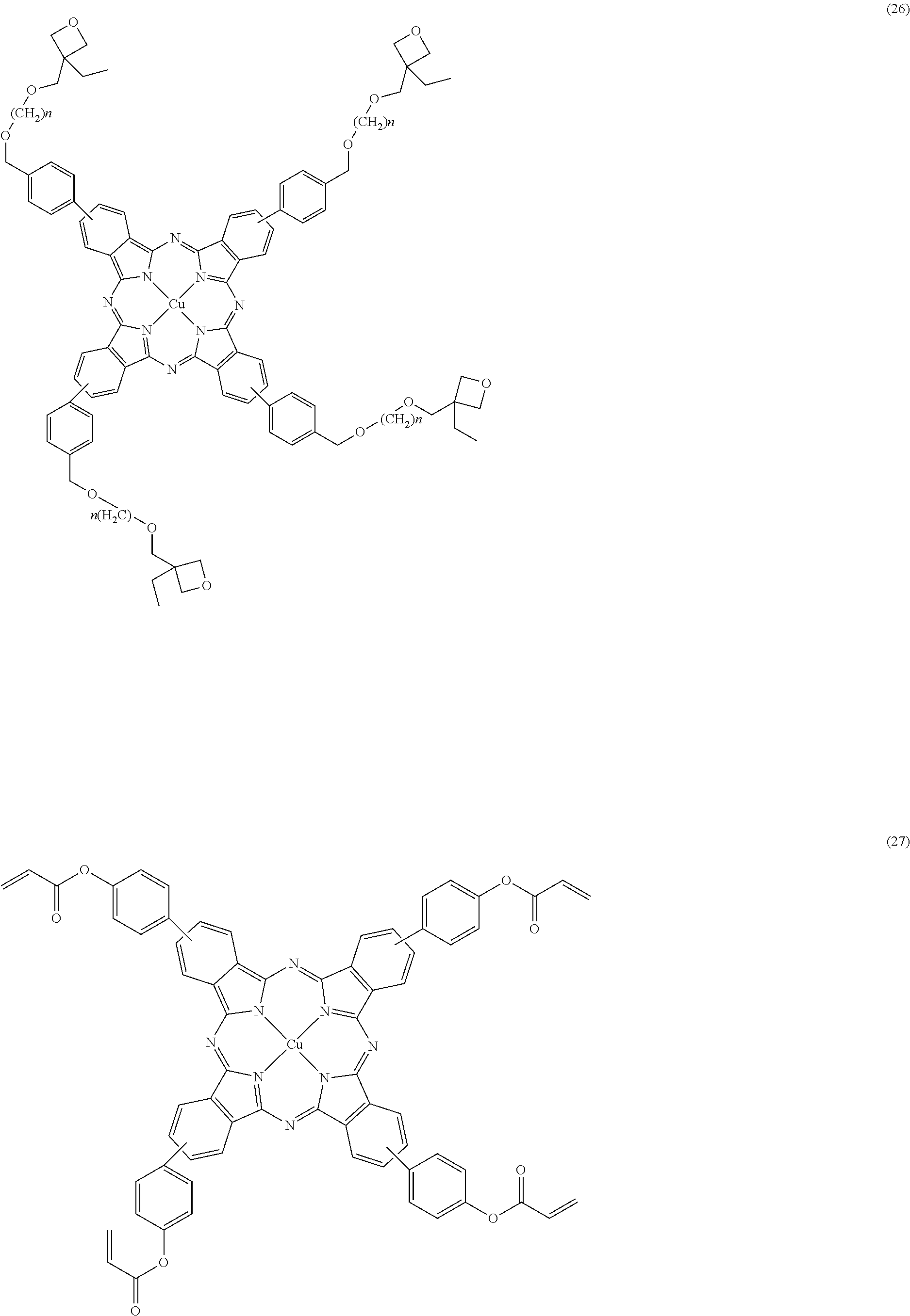

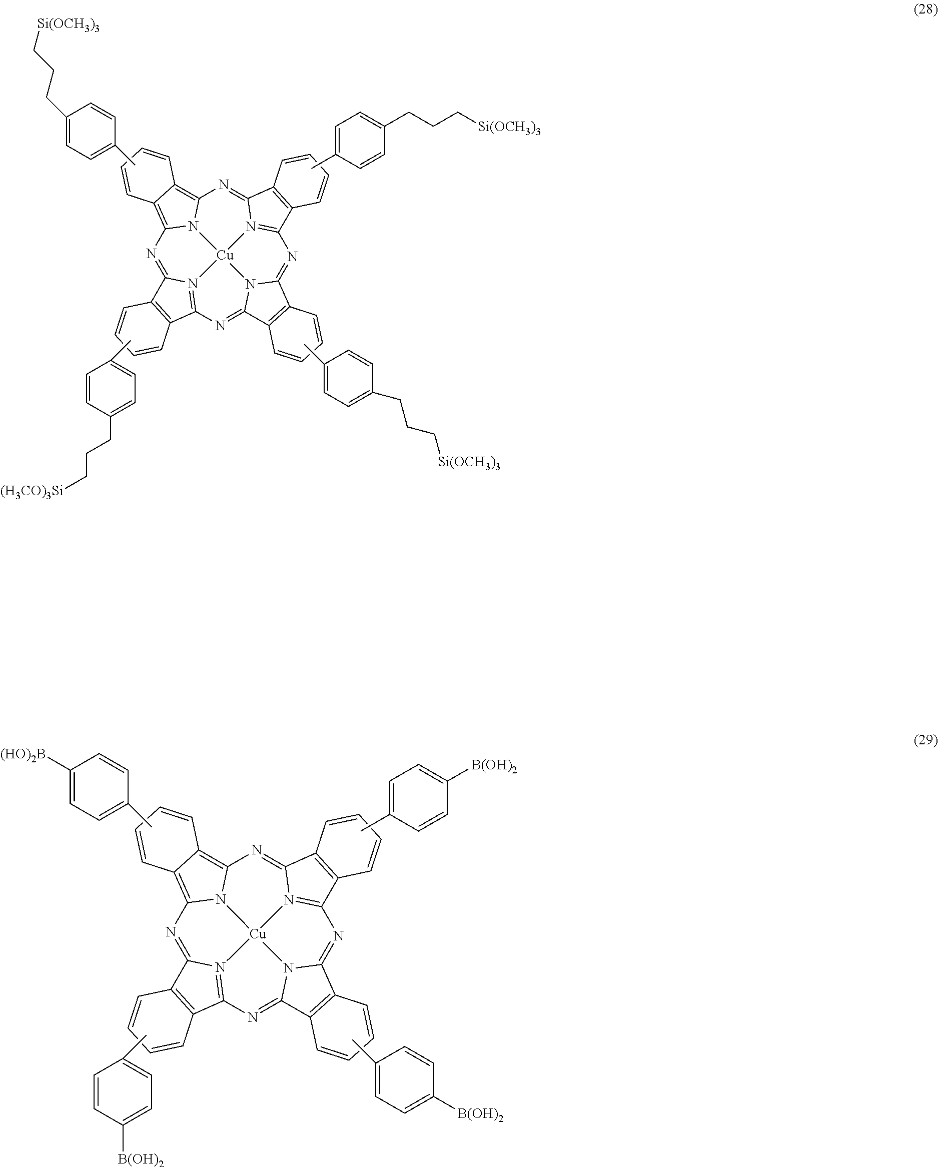

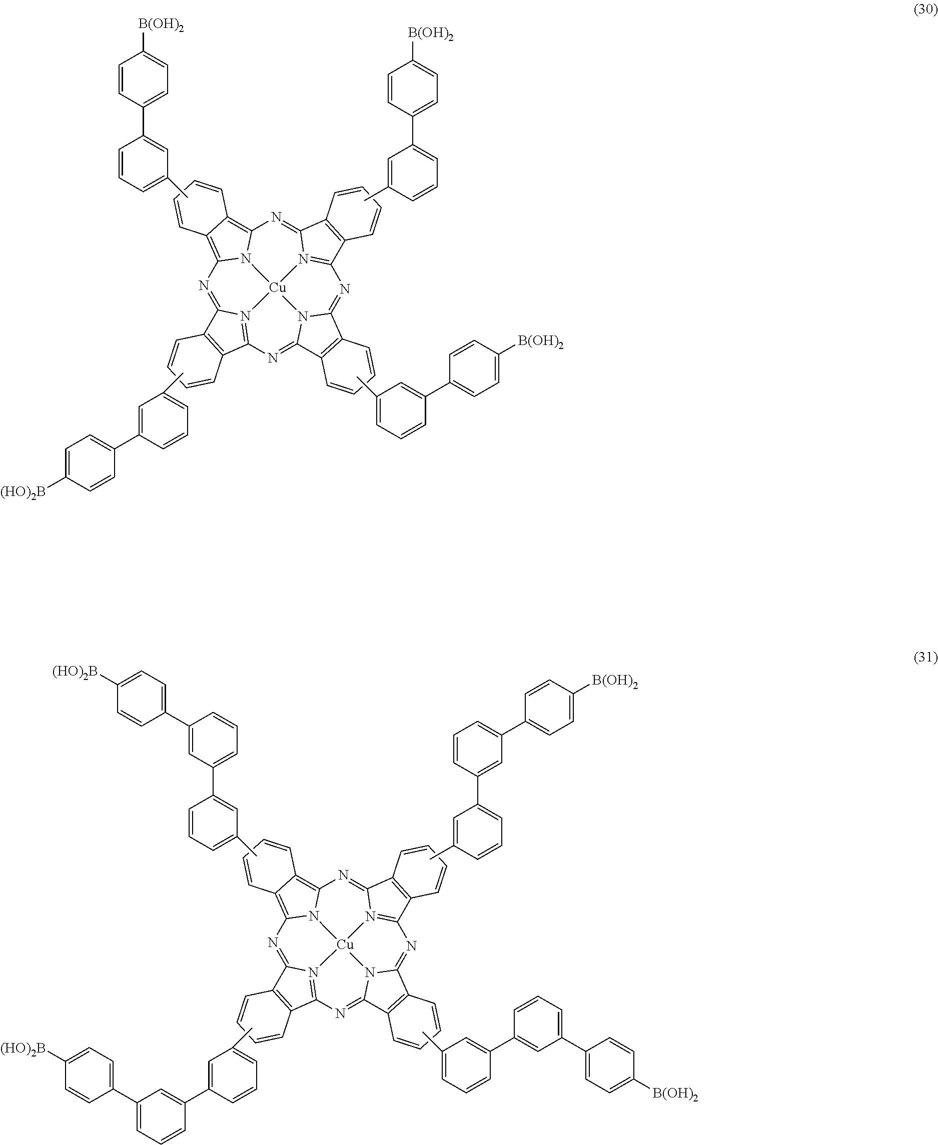

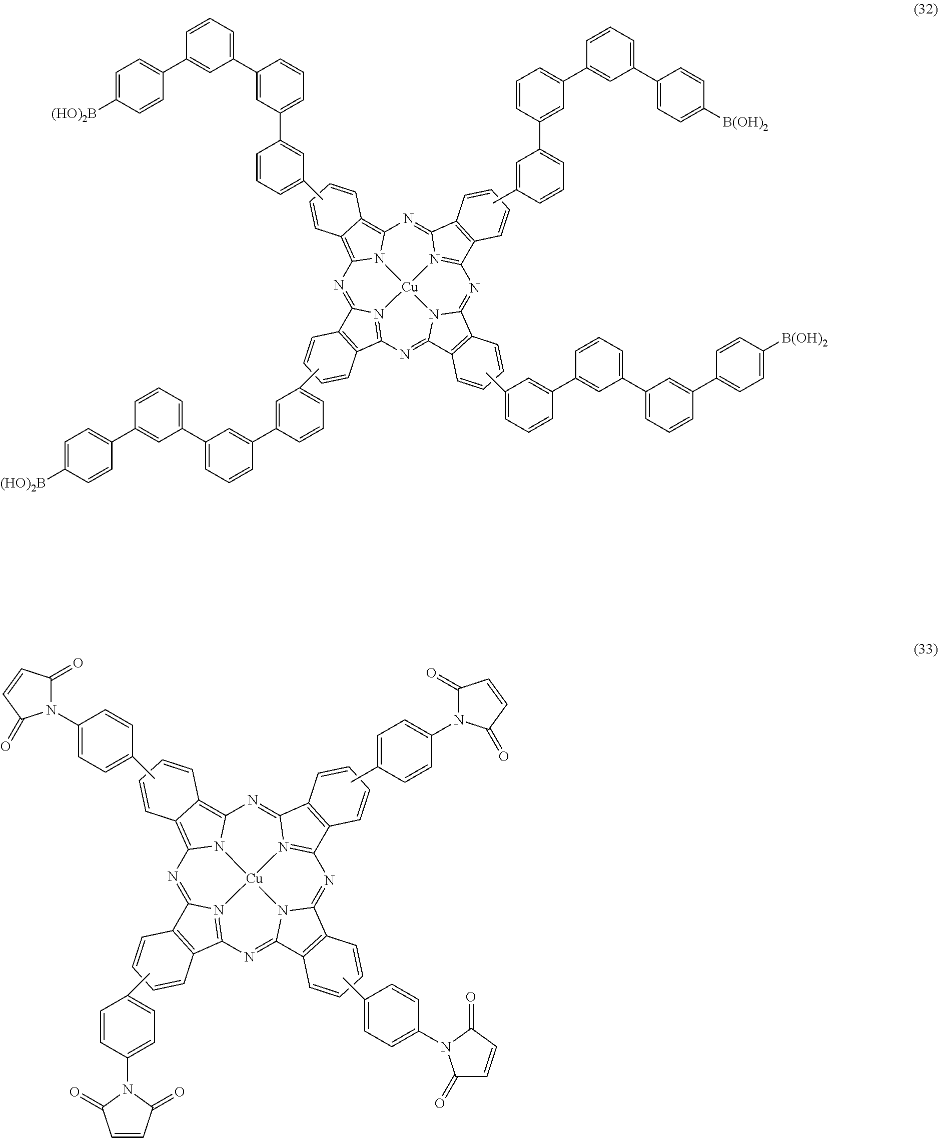

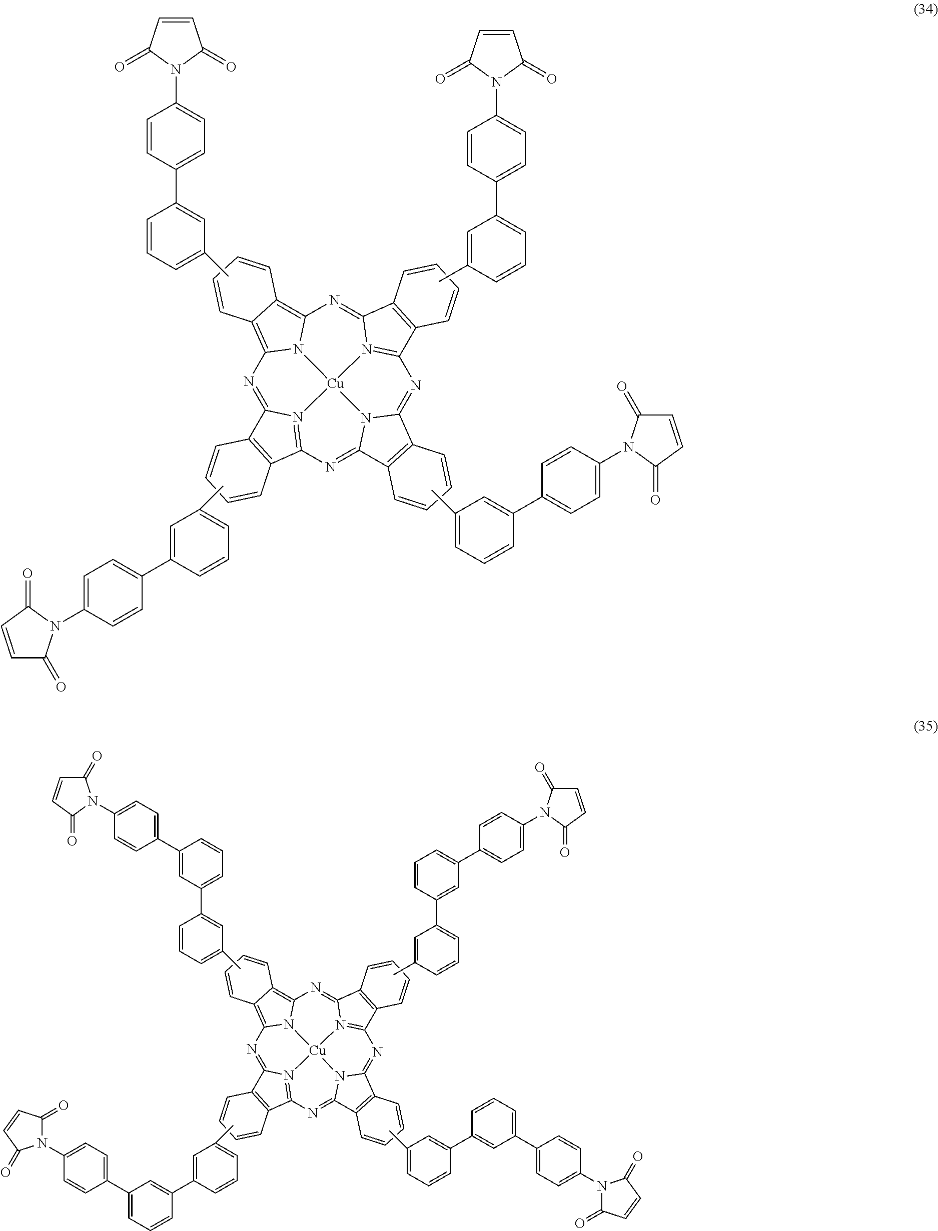

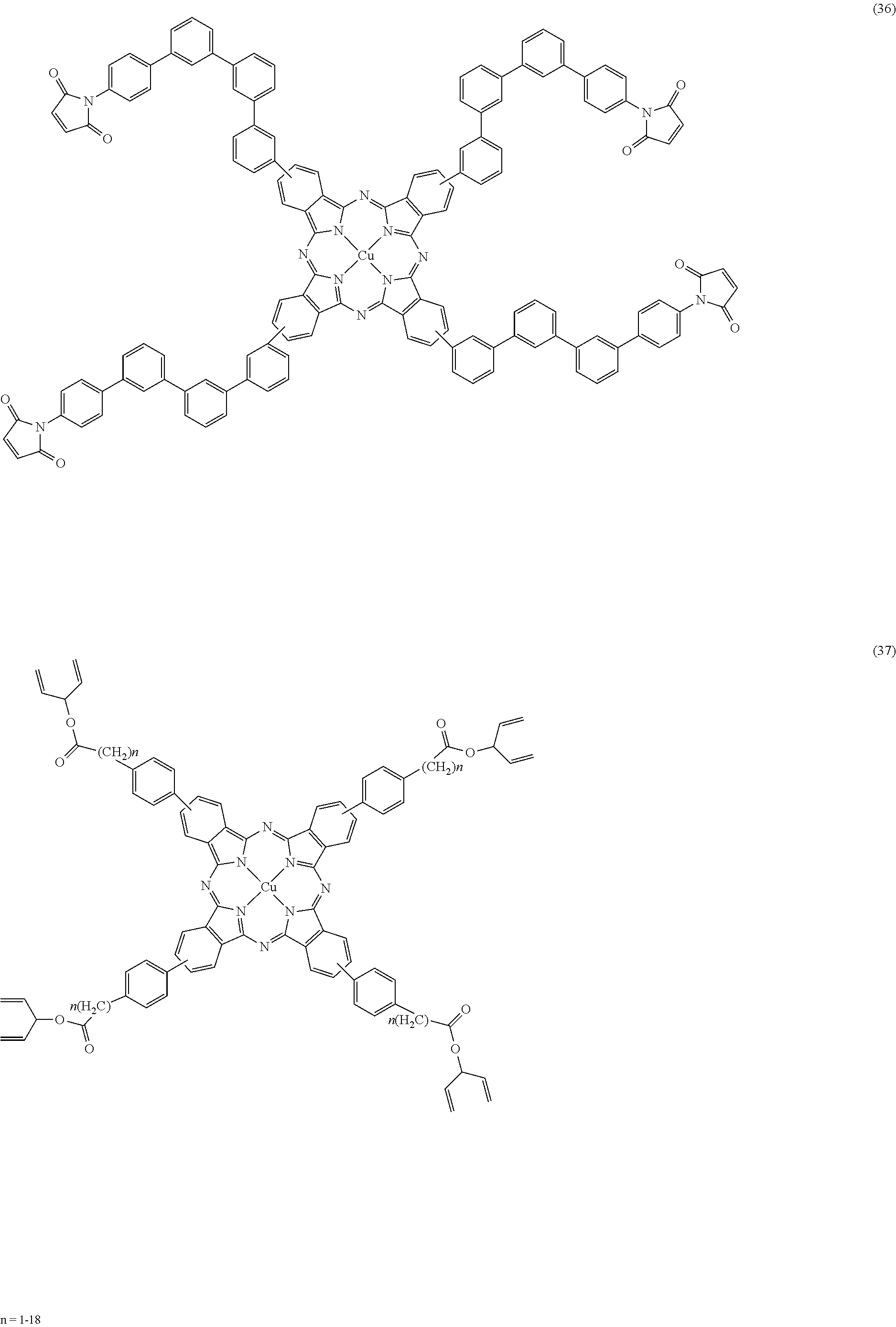

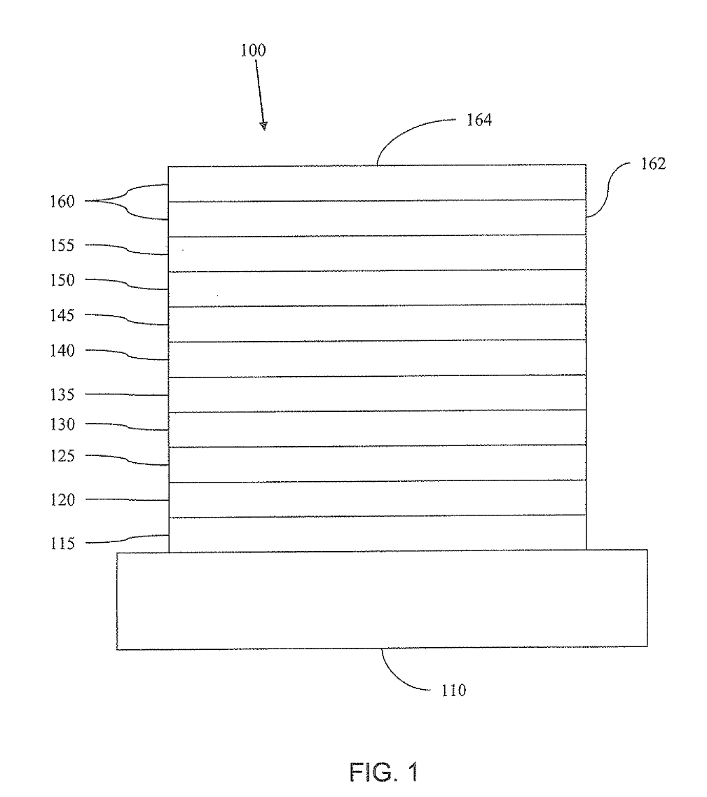

The cross-linkable copper complexes of the present invention may be used in the fabrication of a variety of organic electronic devices, including organic light emitting devices (OLEDs), organic field-effect transistors (OFETs), organic thin-film transistors (OTFTs), and organic photovoltaic devices. For example, FIG. 1 shows an OLED 100 that may be made using the present invention. OLED 100 has an architecture that is well-known in the art (see, for example, U.S. Appln. Publication No. 2008/0220265 entitled “Cross-Linkable Iridium Complexes and Organic Light-Emitting Devices Using the Same” by Xia et al., which is incorporated by reference herein). As seen in FIG. 1, OLED 100 has a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, and a cathode 160. Cathode 160 is a compound cathode having a first conductive layer 162 and a second conductive layer 164. Where a first component (e.g., a layer) of an organic electronic device is described as being “over” a second component, the first component is disposed further away from the substrate. There may be other components (e.g., layers) between the first and second components, unless it is specified that the first component is “in physical contact with” the second component. For example, in an OLED, a cathode may be described as being disposed “over” an anode, even though there are various organic layers in between.

As such, in another aspect, the present invention provides a method of making an organic electronic device. The method comprises providing a solution containing a cross-linkable copper complex of the present invention. The copper complex may be dissolved or dispersed in any of various organic solvents known or proposed to be used in the fabrication of OLEDs by solution processing (e.g., THF, cyclohexanone, chloroform, 1,4-dioxane, acetonitrile, ethyl acetate, tetralin, chlorobenzene, toluene, xylene, anisole, mesitylene, methylisobutyl ketone, tetralone, or mixtures thereof). In some cases, the concentration of the cross-linkable copper complex in the solution is 2 wt % or less.

The solution may also contain a conductivity dopant. As used herein, “conductivity dopant” means an organic small molecule that increases the conductivity of an organic layer of an organic electronic device when applied to the organic layer as an additive. For example, the conductivity dopant may be any of those described in the patent document EP 1 725 079 (Mitsubishi Chemical Corp.) or U.S. Appln. Publication No. 2007/0207341 (Iida et al.). In some cases, the conductivity dopant may have reactive functional groups (such as those described in U.S. Application Ser. No. 61/076,397 entitled “Cross-Linkable Ionic Compounds” by Xia et al., which is incorporated by reference herein) which are capable of cross-linking with the cross-linkable copper complex. In some cases, the concentration of the conductivity dopant in the solution is 0.5 wt % or less.

The solution containing the cross-linkable copper complex is deposited over a first electrode, which may be an anode or cathode. The deposition may be performed by any of various types of solution processing techniques known or proposed to be used for fabricating organic electronic devices. For example, the solution can be deposited using a printing process, such as inkjet printing, nozzle printing, offset printing, transfer printing, or screen printing; or for example, using a coating process, such as spray coating, spin coating, or dip coating. After deposition of the solution, the solvent is removed, which may be performed using any conventional method such as vacuum drying or heating.

After deposition of the solution, the cross-linkable copper complex is cross-linked to form an organic layer. Cross-linking may be performed by exposing the organic semiconductor material to heat and/or actinic radiation, including UV light, gamma rays, or x-rays. Cross-linking may be carried out in the presence of an initiator that decomposes under heat or irradiation to produce free radicals or ions that initiate the cross-linking reaction. The cross-linking may be performed in-situ during the fabrication of a device.

Having a cross-linked organic layer may be useful in the fabrication of multi-layered organic electronic devices by solution processing techniques. In particular, a cross-linked organic layer can avoid being dissolved, morphologically influenced, or degraded by a solvent that is deposited over it. The cross-linked organic layer may be resistant or insoluble to a variety of solvents used in the fabrication of organic electronic devices, including toluene, xylene, anisole, and other substituted aromatic and aliphatic solvents. Thus, with the underlying organic layer being cross-linked and made solvent resistant, the process of solution deposition and cross-linking can be repeated to create multiple layers.

The organic layer made by this process may be any of the various functional organic layers in an organic electronic device. For example, in the case of an organic light emitting device, the organic layer may be any of the organic layers shown in FIG. 1, such as a hole injection layer. After formation of the organic layer, a second electrode (which may be a cathode or anode) is disposed over the organic layer. As in FIG. 1, there may be other functional organic layers between the two electrodes.

In another aspect, the present invention provides an organic electronic device comprising a functional organic layer disposed between two electrodes, wherein the functional organic layer comprises a cross-linked material having a plurality of copper phthalocyanine molecular subunits that are cross-linked to each other. The functional organic layer may be formed using any suitable method, including the methods described above. In some cases, the cross-linked material comprises a plurality of the following molecular subunits:

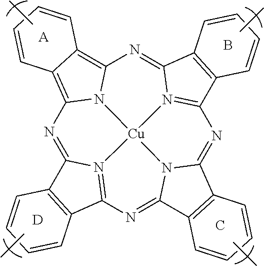

As used herein, “molecular subunit” means a part of a cross-linked polymer derived from a single molecule of monomer. The molecular subunits may be linked to each other via the spacer groups as described above. This functional organic layer may be any of the various types of functional organic layers in an organic electronic device. For example, in the case of an OLED, the functional organic layer may be any of the organic layers shown in FIG. 1, such as a hole injection layer. The functional organic layer may further contain a conductivity dopant as described above. The functional organic layer may be insoluble to various organic solvents used in the fabrication of organic electronic devices, as described above.

### EXAMPLES

Specific representative embodiments of the invention will now be described, including how such embodiments may be made. It is understood that the specific methods, materials, conditions, process parameters, apparatus and the like do not necessarily limit the scope of the invention.

### A. Example Compound 1

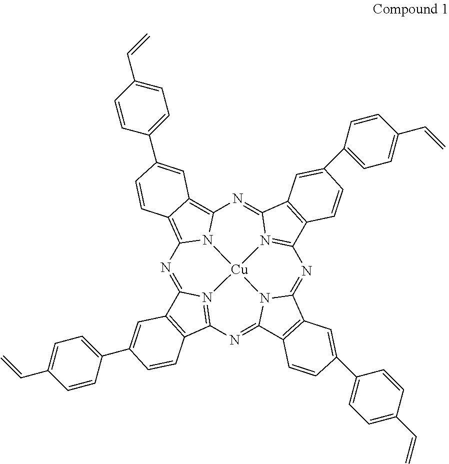

### 1. Synthesis of 4-aminophthalonitrile

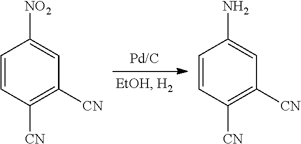

A mixture of 4-nitrophthalonitrile (6.65 g, 38 mmol), Pd/C (4.2 g, 5 wt %), and ethanol (500 mL) was exposed to hydrogen and stirred for 3 hours. The mixture was then filtered and concentrated under reduced pressure to give 4-aminophthalonitrile as a white solid (5 g, 92% yield).

### 2. Synthesis of 4-iodophthalonitrile

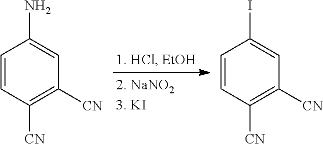

4-Aminophthalonitrile (5 g, 35 mmol) was dissolved in a mixture of ethanol (120 mL) and 10% HCl (120 mL). The reaction was kept at C with an ice bath, then NaNO₂ (3.89 g, 56 mmol) dissolved in water (50 mL) was added slowly into the solution. The reaction was stirred for 30 mins, then KI (9.93 g, 60 mmol) dissolved in water (50 mL) was added slowly. After warming to room temperature, the reaction was stirred overnight. The precipitation was collected by filtration and washed with water to give 4-iodophthalonitrile (7.8 g, 87% yield) as a dark yellow solid.

### 3. Synthesis of 4-vinylphenylphthalonitrile

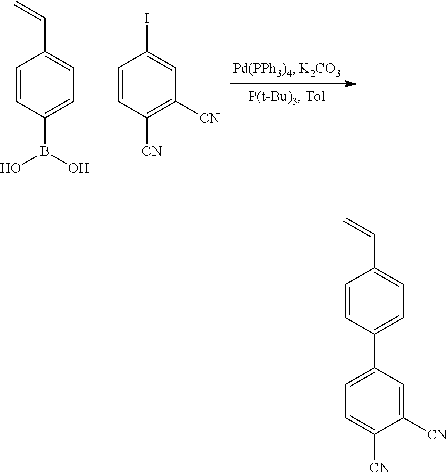

A mixture of 4-vinylphenylboronic acid (291 mg, 2 mmol), 4-iodophthalonitrile (500 mg, 2 mmol), tri-tert-butylphosphine (1.2 mL, 0.5M in toluene), Pd(PPh₃)₄ (35 mg, 0.03 mmol), K₂CO₃ (6 mL, 2M), and toluene (15 mL) was refluxed for 9 hours under argon. The organic layer was separated and then the aqueous layer was extracted by EtOAc. The combined organic layers were dried over MgSO₄, filtered, and concentrated under reduced pressure. Purification by column chromatography on silica gel eluted with EtOAc/hexane (2/1) yielded 260 mg of 4-vinylphenylphthalonitrile.

### 4. Synthesis of Compound 1

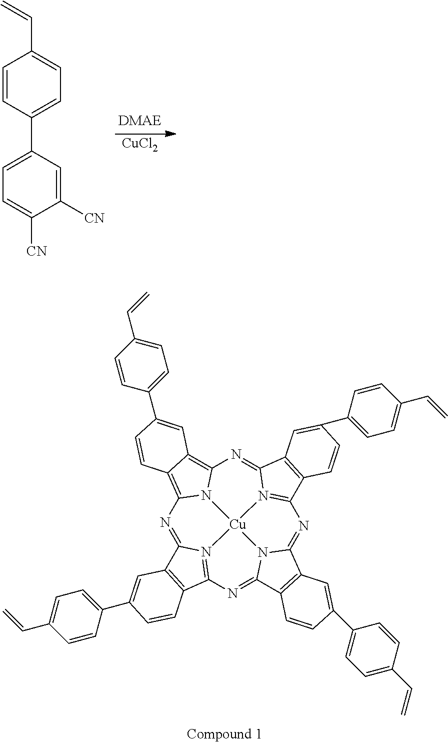

A mixture of 4-vinylphenylphthalonitrile (230 mg, 1 mmol) and CuCl₂ (32 g, 0.25 mmol) in dimethylaminoethanol (DMAE) (1 mL) was heated under argon at reflux temperature for 12 h. The reaction mixture was added to MeOH and the precipitate washed with MeOH, EtOAc and THF to yield 172 mg (70%) of Compound 1 as a green solid.

### B. Example Compound 2

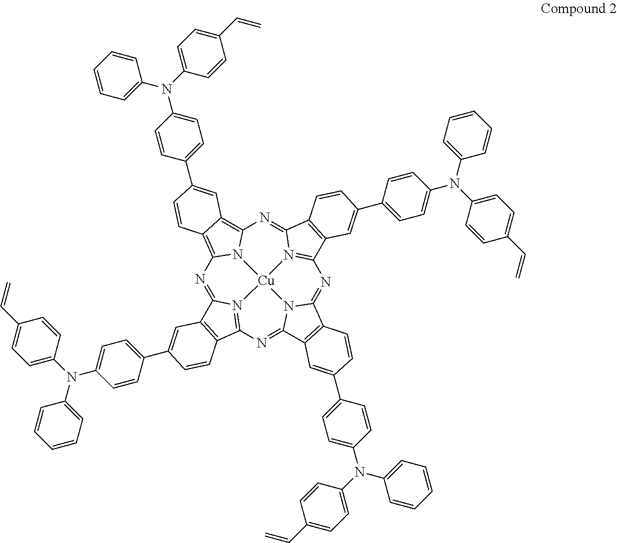

### 1. Synthesis of 4-((4-bromophenyl)(phenyl)amino)benzaldehyde

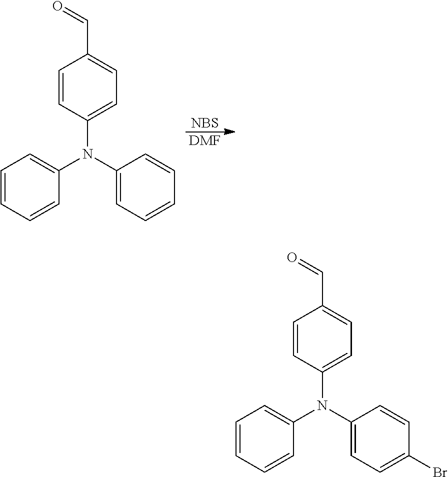

4-(Diphenylamino)benzaldehyde (10 g, 36.5 mmol) was dissolved in DMF (200 mL) and cooled to 0° C. by an ice bath. Then NBS (6.5 g, 36.5 mmol) in DMF (150 mL) was added dropwise into the solution. The reaction was stirred for one hour, then ethyl acetate (300 mL) was added. The organic solution was washed with H₂O, and dried over MgSO₄, and concentrated under reduced pressure to give 4-((4-bromophenyl)(phenyl)amino)benzaldehyde as a yellow oil (12.9 g), which was used directly for the next step without further purification.

### 2. Synthesis of 4-(phenyl(4-(4,4,5,5-tetramethyl-1,3,2-dioxaborolan-2-yl)phenyl)amino)benzaldehyde

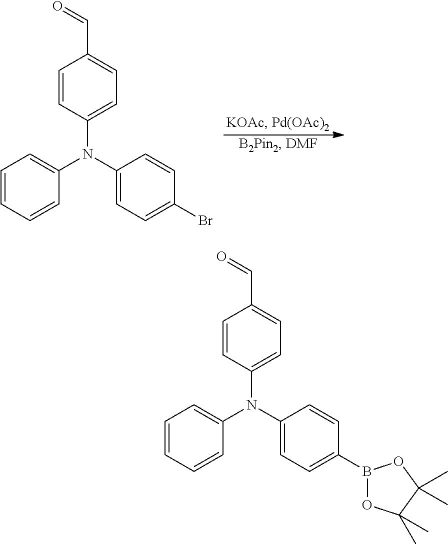

A mixture of bis(pinacolato)diboron (9.6 g, 38 mmol), KOAc (13.6 g, 137 mmol), and 4-((4-bromophenyl)(phenyl)amino)benzaldehyde (12.8 g, 36 mmol) together with Pd(OAc)₂ (456 mg) was degassed in DMF (200 mL) for 30 mins. The reaction mixture was stirred overnight at 90° C. under argon. The black precipitate was filtered off and ethyl acetate (300 mL) was added to the mixture. The organic layer was washed with H₂O and dried over MgSO₄, and the solvent concentrated under reduced pressure to give 4-(phenyl(4-(4,4,5,5-tetramethyl-1,3,2-dioxaborolan-2-yl)phenyl)amino)benzaldehyde as a yellow oil (12.3 g), which was used directly for the next step without further purification.

### 3. Synthesis of 4′-((4-formylphenyl)(phenyl)amino)biphenyl-3,4-dicarbonitrile

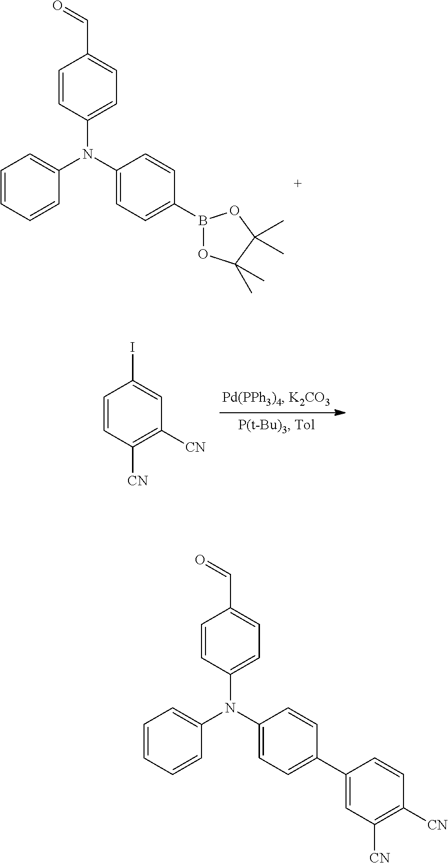

A mixture of 4-(phenyl(4-(4,4,5,5-tetramethyl-1,3,2-dioxaborolan-2-yl)phenyl)amino)benzaldehyde (6 g, 15 mmol), 4-iodophthalonitrile (4.2 g, 16.5 mmol), tri-tert-butylphosphine (35 mL, 0.5M in toluene), Pd(PPh₃)₄ (868 mg, 0.75 mmol), 2 M K₂CO₃ (35 mL), and toluene (100 mL) was refluxed for two days under argon. The organic layer was separated and the aqueous layer was extracted by dichloromethane. The combined organic layers were dried over MgSO₄, filtered, and concentrated under reduced pressure. Purification by column chromatography on silica gel elated by EtOAc/hexane (1/4) yielded 3.25 g of 4′-((4-formylphenyl)(phenyl)amino)biphenyl-3,4-dicarbonitrile. The total yield of the last three steps was 22%.

### 4. Synthesis of 4′-(phenyl(4-vinylphenyl)amino)biphenyl-3,4-dicarbonitrile

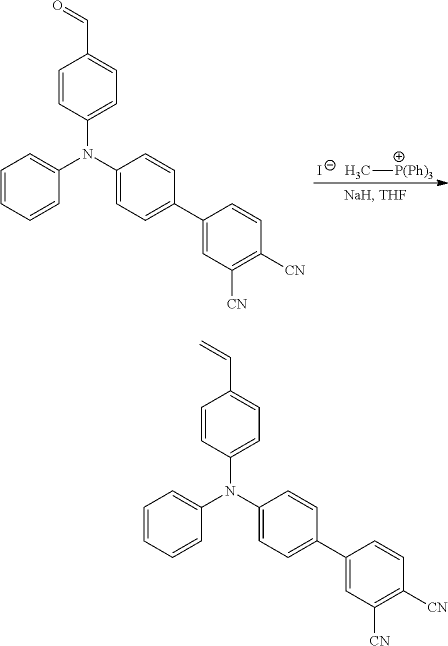

A mixture of methyl(triphenyl)phosphonium iodide (6.83 g, 16.9 mmol) and sodium hydride (406 mg, 16.9 mmol) in dry THF (80 mL) was stirred at room temperature under argon for one hour. This mixture was slowly added into a mixture of 4′-((4-formylphenyl)(phenyl)amino)biphenyl-3,4-dicarbonitrile (2.25 g, 5.6 mmol) in dry THF (80 mL) at 0° C. with an ice bath. The reaction mixture was stirred for 10 mins. Then 150 mL of water was added and extracted with EtOAc (200 mL×3). The combined organic layer was dried over MgSO₄ and solvent was removed in vacuo. Purification by column chromatography on silica gel eluted by EtOAc/hexane=(1/5) yielded 1.6 g of 4′-(phenyl(4-vinylphenyl)amino)biphenyl-3,4-dicarbonitrile (yield 71%).

### 5. Synthesis of Compound 2

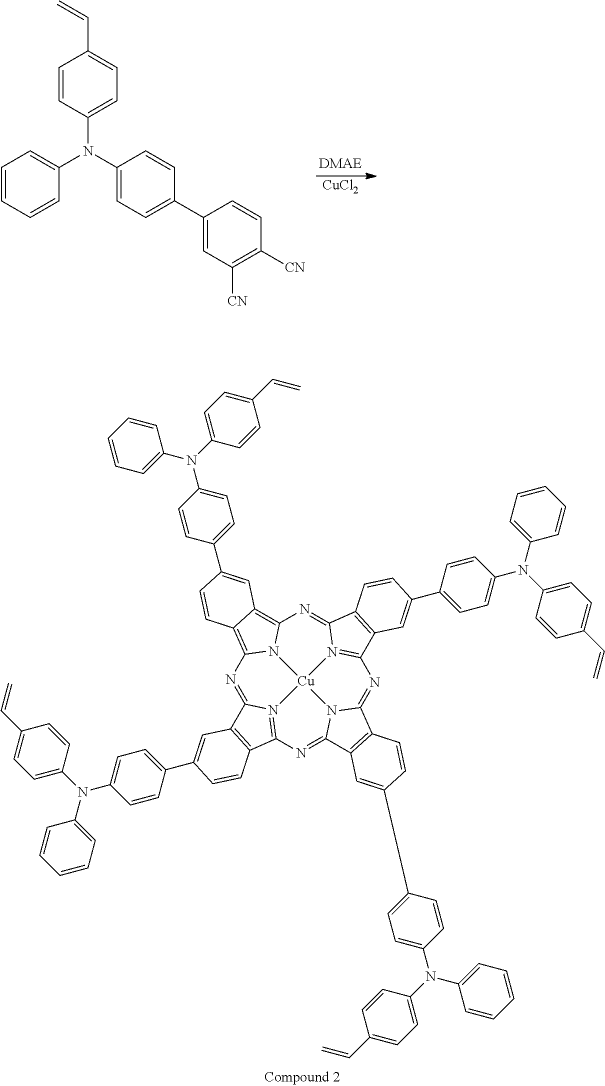

A mixture of 4′-(phenyl(4-vinylphenyl)amino)biphenyl-3,4-dicarbonitrile (1.27 g, 3.2 mmol) and CuCl₂ (107.5 mg, 0.8 mmol) in 4 mL of dimethylaminoethanol (DMAE) was heated under argon at reflux temperature for 12 hrs. The reaction mixture was added to MeOH and the precipitate washed with MeOH and EtOAc. The resulting black solid was recrystallized from pyridine and EtOAc to give 550 mg (yield 42%) of Compound 2 as a deep blue solid.

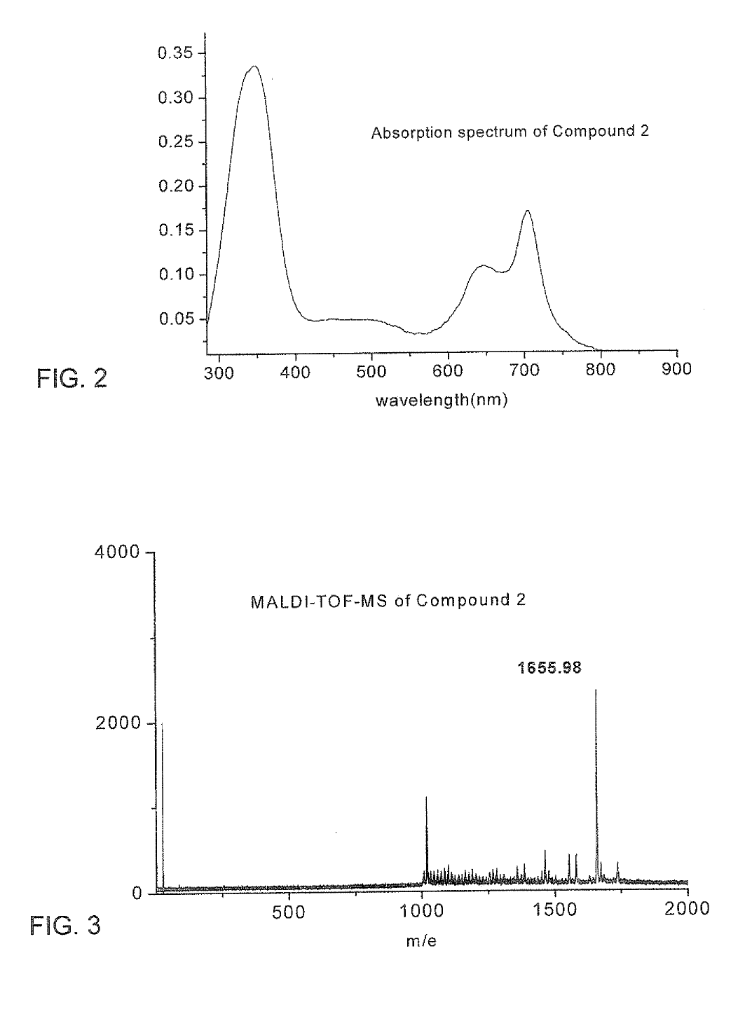

FIG. 2 shows the absorption spectrum of Compound 2. FIG. 3 shows time-of-flight mass spectrometry results of Compound 2.

### C. Green-Emitting Devices

Green-emitting OLEDs were made using Compound 1 and Compound 2 as host materials for the hole injection layer, along with conducting Dopant-A. For making the hole injection layer, either Compound 1 or Compound 2 was dissolved in cyclohexanone at a concentration of 0.5 wt %, along with conducting Dopant-A. The concentration of conducting Dopant-A was 0.015 wt % for the Compound 1 solution and 0.05 wt % for the Compound 2 solution. To form the hole injection layer (HIL), the solution was spin-coated at 4000 rpm for 60 seconds onto a patterned indium tin oxide (ITO) electrode. The resulting film was baked for 30 minutes at 250° C. The film became insoluble after baking.

A comparative green-emitting device was fabricated using PEDOT:PSS (Baytron, CH8000) as the HIL material. The PEDOT:PSS in an aqueous dispersion was spin-coated at 4000 rpm for 60 seconds onto a patterned indium tin oxide (ITO) electrode. The resulting film was baked for 5 minutes at 200° C.

On top of the HIL, a hole transporting layer (HTL) and then emissive layer (EML) were also formed by spin-coating. The HTL was made by spin-coating a 0.5 wt % solution of the hole transporting material HTL-1 in toluene at 4000 rpm for 60 seconds. The HTL film was baked at 200° C. for 30 minutes. After baking, the HTL became an insoluble film.

The EML was made using Host-1 as the host material and the green-emitting phosphorescent Dopant-1 as the emissive material. To form the EML, a toluene solution containing Host-1 and Dopant-1 (of total 0.75 wt %), with a Host-1:Dopant-1 weight ratio of 88:12, was spin-coated onto the insoluble HTL at 1000 rpm for 60 seconds, and then baked at 100° C. for 30 minutes.

The hole blocking layer (containing the compound HPT), the electron transport layer (containing Alq₃), the electron injection layer (containing LiF), and the aluminum electrode were sequentially vacuum deposited.

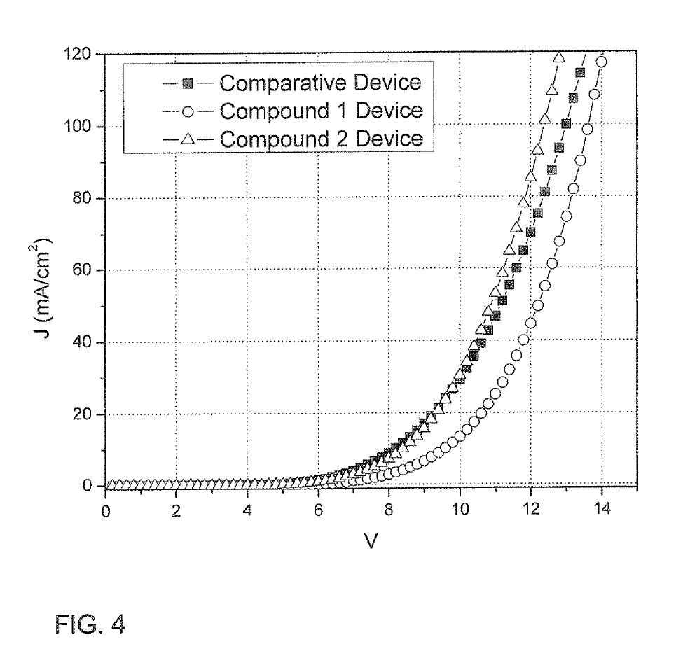

For performance testing, these green-emitting devices were operated under a constant DC current. FIG. 4 shows a plot of the current density versus applied voltage for the devices. The Compound 1 device had a lower current density than the Compound 2 device due to the lower concentration of conducting Dopant-A in the Compound 1 device; the current density at 10 V was 12.7 mA/cm² for the Compound 1 device and 30.4 mA/cm² for the Compound 2 device. Another Compound 2 device was made with a Dopant-A concentration of 0.015 wt %, and the luminous efficiency of this Compound 2 device was only 14 cd/A at 4,000 cd/m².

Table 1 below summarizes the performance of these green-emitting devices. As seen in Table 1, the Compound 1 and Compound 2 devices had much longer lifetimes (as measured by the time elapsed for decay of brightness to 80% of the initial level) than the comparative PEDOT:PSS device.

TABLE 1
Operating performance of the green-emitting devices.

| | Comparative | Compound 1 | Compound 2 |
|---|---|---|---|
| | Device | Device | Device |
| Operating Voltage | 8.1 | 9.6 | 8.6 |
| (V) @ 4,000 cd/m² | | | |
| Current Density | 9.5 | 10.2 | 11.7 |
| (mA/cm²) @ 4,000 cd/m² | | | |
| Luminous Efficiency | 42 | 40 | 34 |
| (cd/A) @ 4,000 cd/m² | | | |
| Lifetime LT₈₀ | 9 | 240 | 170 |
| (hours) from 4,000 cd/m² | | | |
| Color Coordinate | (0,36, 0.60) | (0.33, 0.62) | (0,32, 0.63) |
| CIE 1931 (x, y) | | | |

### D. Red-Emitting Devices

Red-emitting OLEDs were also made using Compound 1 and Compound 2 as host materials for the hole injection layer. For making the hole injection layer, either Compound 1 or Compound 2 was dissolved in cyclohexanone at a concentration of 0.5 wt %, along with conducting Dopant-A at a concentration of 0.05 wt % for both. The solution was spin-coated at 1000 rpm for 60 seconds onto a patterned indium tin oxide (ITO) electrode. The resulting film was baked for 30 minutes at 250° C. The HIL film became insoluble after baking.

A comparative red-emitting device was fabricated using PEDOT:PSS (Baytron, CH8000) as the HIL material. The PEDOT:PSS solution was spin-coated at 4000 rpm for 60 seconds onto a patterned indium tin oxide (ITO) electrode. The resulting film was baked for 5 minutes at 200° C.

On top of the HIL, a hole transporting layer (HTL) and then emissive layer (EML) were also formed by spin-coating. The HTL was made by spin-coating a 1.0 wt % solution of the hole transporting material HTL-1 in toluene at 4000 rpm for 60 seconds. The HTL film was baked at 200° C. for 30 minutes. After baking, the HTL became an insoluble film.

The EML was made using two host materials (Host-1 and Host-2) mixed with a red-emitting Dopant-2 in toluene. Host-2 is the same material as the green-emitting Dopant-1 used above for the green-emitting device, except that it was used as a co-host (Host-2) for the red-emitting devices. The weight ratio for Host-1:Host-2:red-emitting Dopant-2 was 7:2:1. To form the EML, a toluene solution containing Host-1, Host-2, and red Dopant-2 (of total 0.75 wt %) was spin-coated onto the insoluble HTL at 2000 rpm for 60 seconds, and then baked at 100° C. for 30 minutes.

The hole blocking layer (containing BAlq₂), the electron transport layer (containing Alq₃), the electron injection layer (containing LiF), and the aluminum electrode were sequentially vacuum deposited.

Table 2 below summarizes the performance of these red-emitting devices. As seen in Table 2, the Compound 1 and Compound 2 devices have much longer lifetimes (as measured by the time elapsed for decay of brightness to 80% of the initial level) than the comparative PEDOT:PSS device.

TABLE 2
Operating performance of the red-emitting devices.

| | Comparative | Compound 1 | Compound 2 |
|---|---|---|---|
| | Device | Device | Device |
| Operating Voltage | 9.4 | 11.2 | 11.6 |
| (V) @ 2,000 cd/m² | | | |
| Current Density | 21 | 19.6 | 23.8 |
| (mA/cm²) @ 2,000 cd/m² | | | |
| Luminous Efficiency | 9.6 | 10.3 | 8.2 |
| (cd/A) @ 2,000 cd/m² | | | |
| Lifetime LT₈₀ | 22 | 400 | 220 |
| (hours) from 2,000 cd/m² | | | |
| Color Coordinate | (0.67, 0.33) | (0.67, 0.33) | (0.67, 0.33) |
| CIE 1931 (x, y) | | | |

The foregoing description and examples have been set forth merely to illustrate the invention and are not intended to be limiting. Each of the disclosed aspects and embodiments of the present invention may be considered individually or in combination with other aspects, embodiments, and variations of the invention. In addition, unless otherwise specified, none of the steps of the methods of the present invention are confined to any particular order of performance. Modifications of the disclosed embodiments incorporating the spirit and substance of the invention may occur to persons skilled in the art and such modifications are within the scope of the present invention.

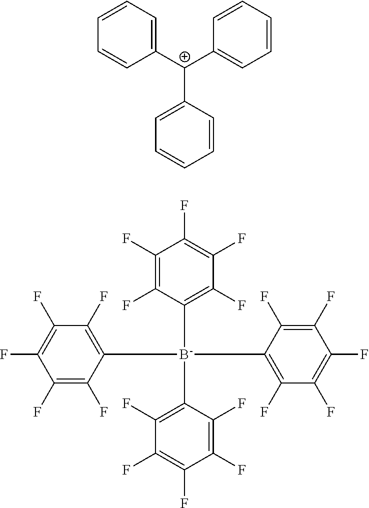

### Conducting Dopant-A

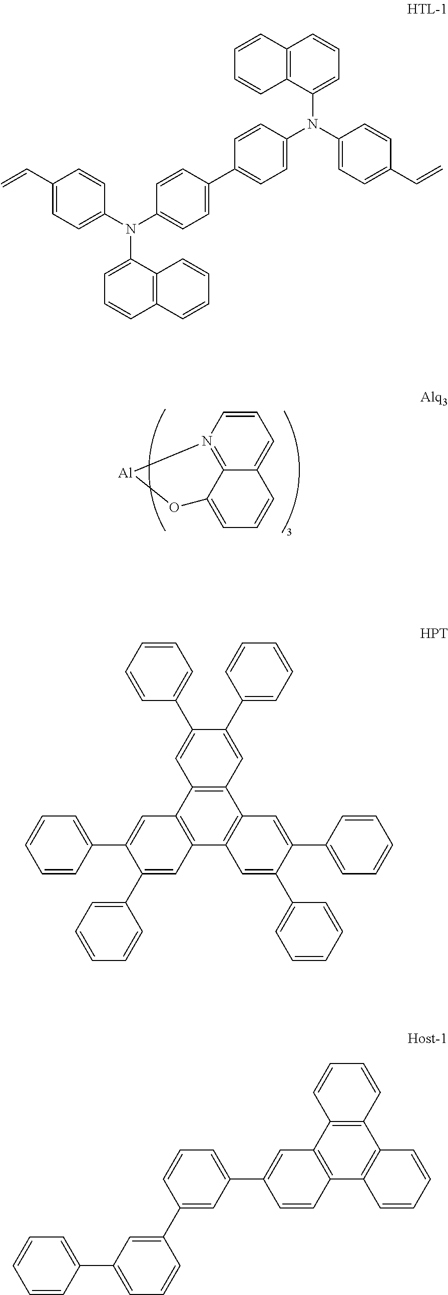

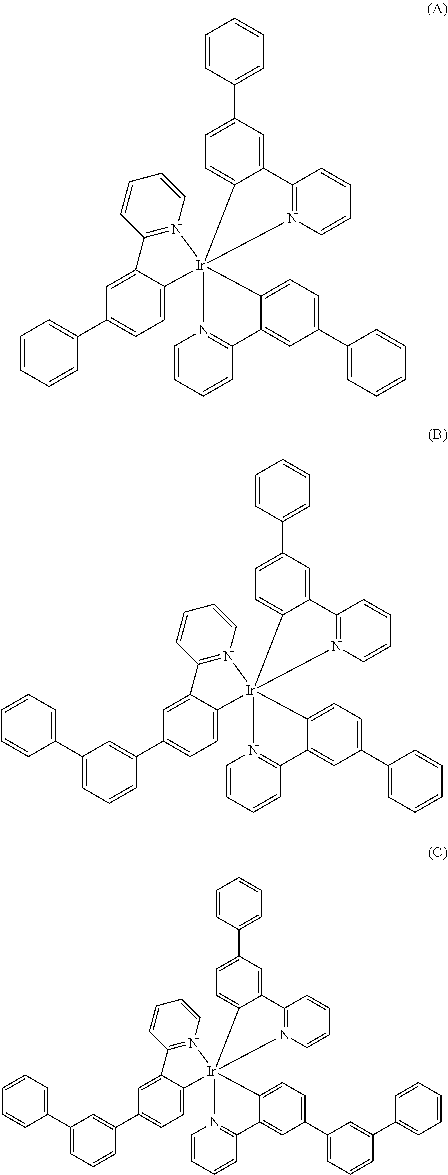

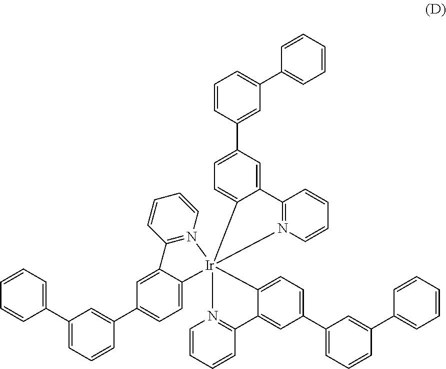

Green-emitting Dopant-1 (or Host-2 for red-emitting device) is a mixture of A, B, C, and D in a ratio of 1.9:18.0:46.7:32.8

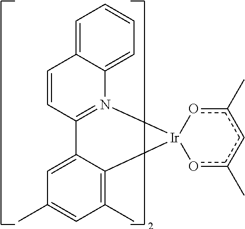

### Red-Emitting Dopant-2:

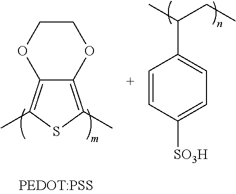

We claim:

1. A cross-linkable copper complex having the following structure: 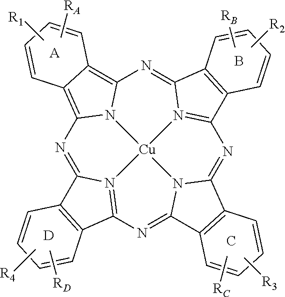
wherein R₁, R₂, R₃, and R₄ are each independently one or more optional substitutions with the proviso that at least one of R₁, R₂, R₃, and R₄ is a substitution comprising a spacer group and one or more cross-linkable functionalities on the spacer group, wherein the spacer group comprises a chain of one or more aryl groups; and
wherein R_{A}, R_{B}, R_{C}, and R_{D} are each independently one or more optional substitutions on any position of their respective rings A, B, C, and D, and each substitution being independently selected from the group consisting of: lower aliphatic, lower aryl, lower heteroaryl, and halogen.

2. The copper complex of claim 1, wherein the chain of one or more aryl groups is directly linked to the phthalocyanine core.

3. The copper complex of claim 1, wherein the spacer group separates the cross-linkable functionality from the phthalocyanine core by a distance of at least 4 bond lengths.

4. The copper complex of claim 1, wherein the one or more aryl groups in the chain are monocyclic aryl groups.

5. The copper complex of claim 4, wherein the chain consists of 1-5 monocyclic aryl groups.

6. The copper complex of claim 4, wherein the chain contains 2 or more monocyclic aryl groups that are linked to each other via meta-linkages.

7. The copper complex of claim 1, wherein the spacer group contains an amine group.

8. The copper complex of claim 1, wherein the spacer group is represented by the following structure: 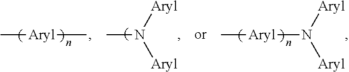
wherein n=1-6 and the aryl groups in the spacer group are the same or different.

9. The copper complex of claim 1, wherein each cross-linkable functionality is independently selected from the group consisting of: vinyl, acrylate, epoxide, oxetane, trifluoroethylene, fused cyclobutene, siloxane, maleimide, cyanate ester, ethynyl, nadimide, phenylethynyl, biphenylene, phthalonitrile, and boronic acid.

10. The copper complex of claim 1, wherein the spacer group further comprises one or more aliphatic linkage units.

11. The copper complex of claim 1, wherein the copper complex has a molecular weight of 3,000 or less.

12. A method of forming an organic layer, comprising:
providing a solution containing a cross-linkable copper complex that comprises a phthalocyanine core and one or more cross-linkable functionalities linked to the phthalocyanine core;
depositing the solution on a surface; and
cross-linking the cross-linkable copper complex to form an organic layer on the surface.

13. The method of claim 12, wherein the concentration of the cross-linkable copper complex is 2 wt % or less.

14. The method of claim 12, wherein the solution further contains a conductivity dopant.

15. The method of claim 14, wherein the conductivity dopant has a reactive functional group capable of cross-linking with the cross-linkable copper complex.

16. The method of claim 14, wherein the concentration of the conductivity dopant is 0.5 wt % or less.

17. The method of claim 12, wherein the organic layer is insoluble in toluene.

18. The method of claim 12, wherein the cross-linkable copper complex has the following structure: 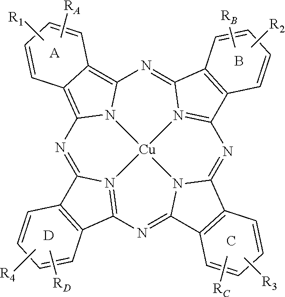
wherein R₁, R₂, R₃, and R₄ are each independently one or more optional substitutions with the proviso that at least one of R₁, R₂, R₃, and R₄ is a substitution comprising a spacer group and one or more cross-linkable functionalities on the spacer group, wherein the spacer group comprises a chain of one or more aryl groups; and
wherein R_{A}, R_{B}, R_{C}, and R_{D} are each independently one or more optional substitutions on any position of their respective rings A, B, C, and D, and each substitution being independently selected from the group consisting of: lower aliphatic, lower aryl, lower heteroaryl, and halogen.

19. The method of claim 12, wherein the cross-linkable copper complex has a molecular weight of 3,000 or less.

20. An organic electronic device comprising:
a first electrode;
a second electrode disposed over the first electrode; and
an organic layer disposed between the first electrode and the second electrode, wherein the organic layer is formed by the method of claim 12.

21. The device of claim 20, wherein the electronic device is an organic light emitting device.

22. The device of claim 22, wherein the organic layer is a hole injection layer.

23. The device of claim 20, wherein the organic layer further comprises a conductivity dopant.

24. The device of claim 24, wherein the conductivity dopant is cross-linked with the cross-linkable copper complex.

25. An organic electronic device comprising:
a first electrode;
a second electrode disposed over the first electrode; and
an organic layer disposed between the first electrode and the second electrode, wherein the organic layer comprises a cross-linked material having a plurality of cross-linked copper phthalocyanine molecular subunits.

26. The device of claim 25, wherein the cross-linked copper phthalocyanine molecular subunits have the following structure:

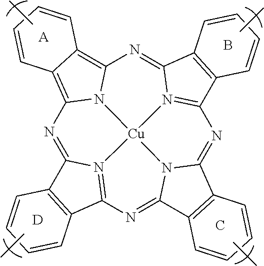

27. The device of claim 25, wherein the molecular subunits are linked to each other by spacer groups, each spacer group comprising a chain of one or more aryl groups.

28. The device of claim 27, wherein each chain of one or more aryl groups is directly linked to the copper phthalocyanine molecular subunit.

29. The device of claim 27, wherein the spacer groups separate the copper phthalocyanine molecular subunits from each other by a distance of at least 4 bond lengths.

30. The device of claim 27, wherein the one or more aryl groups in the chain are monocyclic aryl groups.

31. The device of claim 30, wherein the chain consists of 1-5 monocyclic aryl groups.

32. The device of claim 30, wherein the chain contains 2 or more monocyclic aryl groups that are linked to each other via meta-linkages.

33. The device of claim 27, wherein each spacer group contains an amine group.
